(19) United States
(12) Patent Application Publication
(10) Pub. No.: US 2026/0196282 A1
(43) Pub. Date: Jul. 9, 2026

(54) ENERGY SAVING, SIZE REDUCTION, AND PERFORMANCE ENHANCEMENT WITH CHARGE DOMAIN DIGITAL LOGIC AND MEMORY

(71) Applicant: AlStorm Inc., Houston, TX (US)

(72) Inventors: David Schie, Fort Myers, FL (US); Scott Johnson, Boise, ID (US); Martin Apro, Graz (AT)

(73) Assignee: AIStorm Inc.,, Houston, TX (US)

(21) Appl. No.: 19/438,165

(22) Filed: Dec. 31, 2025

Related U.S. Application Data
(60) Provisional application No. 63/742,141, filed on Jan. 6, 2025.

(51) Int. Cl. G11C 19/28; G11C 11/406; H03K 3/037; H03K 19/21; H10D 44/45

(52) U.S. Cl. CPC G11C 19/28; G11C 11/406; H03K 3/037; H03K 19/21; H10D 44/456

(57) ABSTRACT

Methods and structures are provided for digital design logic and memory circuits that overcome the inefficiencies of transistor switch-based designs with alternative charge domain based implementations. Logic gate devices & memory devices in the charge domain are disclosed that are fabricated in smaller than 180 nm processes or 40 nm or smaller FinFET processes that do not suffer from deficiencies of prior charge domain digital based designs. The charge domain logic devices utilize elements including barriers, sinks, charge to barrier devices, charge to voltage devices, voltage to charge devices, thyristors, holdup cells, and similar devices that can be used to create digital circuits and memory circuits both dynamic and static. The combination of these elements may be used to synthesize digital components and memory including logic gates, DRAM, SRAM, shift registers, as well as output drivers for these charge domain digital components and memory.

### RELATED APPLICATIONS

This application claims priority benefit of U.S. Provisional Application Ser. No. 63/742,141 filed on Jan. 6, 2025, 2025, entitled “ENERGY SAVINGS WITH CHARGE DOMAIN DIGITAL”, which is incorporated herein by reference in its entirety. The present patent application claims the benefit under 35 U.S.C § 119(e) of the aforementioned provisional application.

### TECHNICAL FIELD

The present invention relates generally to digital design and more particularly to charge domain digital logic and memory.

### BACKGROUND

Digital circuit design has over several decades turned into an exercise of programmatically describing the synthesis of complex mathematical digital functions. The evolution of electronic design automation (EDA) has allowed an automated method to map these programs into silicon, accelerating development, and producing a trillion-dollar industry. Recently, digital circuit design has begun to reach power, size, and performance limits as further exemplified by the breakdown of Moore's law and the need for increased power generation facilities including nuclear reactors to power local digital compute server farms for cloud-based services and artificial intelligence computations. The reason for the breakdown is that digital gates or memory based on transistor switches have several limitations including poor power performance, loss of charge or leakage, speed limitations, shoot through currents, noise susceptibility, large size, and significant noise generation. To combat limitations of transistor switches, considerable resources have been spent to develop new technologies illustratively including fin field-effect transistors (FinFETs), gate all around (GAA), nanowires, and other structures that attempt to improve the performance of digital circuits or memory structures based upon transistor switch devices. An alternative method of producing digital circuits was considered in the early days of the silicon revolution, however, was abandoned due to size, power, and other limitations.

Digital circuit and memory design has been based completely upon the use of transistor switches for several decades. In the late 1970's and early 1980's, however, another type of digital implementation was in a race for dominance of digital design—a methodology loosely called “charge domain digital.” Charge domain digital relied upon the concepts of barriers, sinks, input diodes and clocks to implement digital functionality by manipulating movement of charge rather than re-directing voltage inputs to outputs through switch configurations as might be expected with transistor switch based digital. Although functional, the charge domain digital based designs at the time had several critical disadvantages versus transistor switch-based circuits including:
the logic gates were too slow
the logic gates were too big
the logic gates accepted voltage inputs but produced charge outputs
converting the charge outputs back to voltages was done by large finite bandwidth op amp circuits, negating much of the gains
the logic gates had to be clocked in complex ways
the logic gates were purely dynamic
the poly gates of the charge coupled elements had to overlap

Some of the reasons for the limitations of charge domain digital based designs included:
the voltage potential had to be shared across multiple metal oxide semiconductor (MOS) capacitors and logic gates
the logic gates used MOS capacitors in the depletion region with no hold up mechanism
the logic gates required operational amplifiers or other reader circuits to convert their charge outputs back to voltages for further use
the planar lithographies of the time were too large limiting fringe effect or capacitive coupling, further requiring overlapping control gates (poly or metal)
non-planar topologies such as fins, GAA, or nanowire were not available
the logic gates had to be clocked and were not level or edge triggered
no mechanism existed to accept a charge input for logic processing
no mechanism existed to auto-commutate based on a charge input
no mechanism existed to hold logic gate output values to enable static logic

For the above reasons, transistor switch based digital designs won the war and have become the standard for the digital electronics industry. Year after year, significant resources were spent optimizing the transistor switches to reduce their size and improve performance. The primary improvement was the reduction of equivalent gate length which led to many innovations such as FinFETs, GAA (gate all around), or nanowire configurations. The improvements also resulted in the concept of Moore's law where a consistent reduction in size could be expected with time that was linear. Today, this exercise has reached its limits with Moore's law linear improvements in question and the ability to further shrink circuits or improve their efficiency now in doubt.

The rise of new applications including artificial intelligence, blockchain mining, and social networking has exponentially increased the need for digital switch based digital implementations (“digital compute”) such that the inefficiencies of transistor switch-based design are becoming a burden on society as existing power generation infrastructure is struggling to keep up. Furthermore, due to these new applications green initiatives focused on power reduction are being thwarted, silicon processing has become extremely expensive with required unique tools such as ultra-violet (UV) lithography machines, and latency and limited battery life in Internet of things (IoT) and portable devices such as cell phones have become a frustration for the end user.

With respect to implementation of transistor based digital design, automated electronic design tools (EDA tools), utilizing high-definition programming languages such as Verilog or hardware description languages (HDL), are the basis for most development, and it is no longer required to draw schematics using a capture tool for digital designs. Instead, these tools simplify the process such that developing large integrated circuits can be done programmatically, leaving to the EDA software the exercise of converting the programmatical input into their final silicon form often referred to as “place and route” or “polygon placement.” This refers to the actual geometry placed on lithographic masks for the layer-by-layer creation of silicon chips. In fact, the high-level circuit designers who are largely responsible for the “designs” are separated from the actual transistors being placed on silicon and instead spend their time with complex mathematical logic functionality, and timing analysis. High level designers require little or no knowledge of the polygon level transistor switches being fabricated on silicon.

The most basic element of charge domain processing is the transient depletion MOS capacitor formed after a change in gate voltage above a substrate silicon or statically created by an implant (or pinning) under the gate or instead of the gate, or a combination. This is further illustrated in FIG. 1A where the higher the voltage on the gate of the element, the deeper the depletion region. FIG. 1B illustrates the concept of “filling” the element with charge to 80% of its full well capacity by providing a source of charge carriers to “fill” the depletion region. These elements resemble buckets capable of being filled, or partially filled, with charge from the potential of the transient depletion depth will hereinafter be called a ‘charge coupled element’, or a ‘charge register’, a ‘charge storage element’ or a ‘memory node’, or similar nomenclature. A bucket may be formed by raising the voltage on a gate to form the depletion region which will only last temporarily, or a permanent bucket may be formed using an implant, or a combination of a gate over one or more implants over silicon may be used to create potential variations within a bucket or as compared to another bucket with the same voltage on its gate (see FIG. 11 for an example).

FIGS. 2A-2E illustrate movement of charge along a charge coupled device (CCD) shift register. In FIG. 2A charge is resident under a gate with 10V upon it (a). In FIG. 2B 10V is then placed upon the gate of the element to the immediate right of the gate in FIG. 2A causing a depletion region of a similar depth. This in turn causes the charge to spread between the two CCD elements as shown in FIG. 2C. Thereafter, the voltage is lowered on the gate of the left element. A snapshot of the 10V to 0V transition at 5V shows the charge spilling into the third element as shown in FIG. 2D, and finally being resident only under the third element after the voltage on the 2nd element has reached 0V as shown in FIG. 2E. This timing on the gate of the CCD shift register has caused the charge to move from under the second element to under the third element. There are schemes using implants which can reduce the need to have three charge storage elements to store and isolate a charge known to those skilled in the art, an example of which is shown in FIG. 11.

### Source of Charge

For a charge domain circuit to operate a source of charge is required. FIG. 3A shows a diode formed by implanting an n+ region and coupling that n+ region to voltage Vin. If Vin is raised the depletion region under the n+ expands, lowering the potential of the available sea of charge underneath it. If Vin is lowered the depletion region shrinks, raising the potential level of the charge underneath the n+ region. In FIG. 3B a series of charge levels are depicted, where the input diode charge level is set just below the top potential of a barrier formed by the CCD element controlled by VG (t₁ with VG=Vlow, V_{Ø1}=Vhigh). Thereafter, if the voltage on V_{G} is raised (t₂ with VG=Vhigh, V_{Ø1}=Vhigh), then the bottom potential of their respective depletion regions will be below the input diode charge level and charge will flow into the elements under Ø₁ and under V_{G}. If V_{G} is set low again (t₃ with VG=Vlow, V_{Ø1}=Vhigh) then charge will be isolated under Ø₁. Charge can then be shifted as was shown in FIGS. 2A-2E (t₄, t₅). FIG. 3C is a timing diagram showing the times t₁-t₅ used in FIG. 3B.

FIG. 4 shows a prior art AND gate from the 1970's fabricated in 5 um technology. During to, charge moves into the shared long charge coupled element D from one or both of the two input charge coupled elements to the left. If both contained charge then charge will also spill into the area under C (t₀ with V_{Ø1}=Vhigh, V_{Ø2}=Vlow). Thereafter, if Ø₁ is lowered and Ø₂ is raised (t₁ with V_{Ø1}=Vlow, V_{Ø2}=Vhigh) then the charge under C will transfer to the output and the charge in D will flow into the sink.

The circuit in FIG. 4 has several disadvantages. The circuit requires overlapping gates, it is very long due to the 5 um technology, most of the movement is from drift and diffusion which is slow due to limited fringe effect due to the limited potential difference during the spill time, the lack of capacitive coupling and due to the long distance between charged coupled elements. By fabricating logic devices using charge domain barriers, sinks and diodes in modern lithographies smaller than 180 nm the fringe effect and capacitive coupling may be taken advantage of to accelerate charge transfer and eliminate the need for overlapping gates. Also by using a Fin structure in processes smaller than or equal to 40 nm capacitive coupling may be taken advantage of to increase charge transfer and overcome the need for overlapping gates.

### The Advantages of Fringing Fields

Drift and diffusion as illustrated in FIGS. 3A-3C with both depletion buckets enabled is not an efficient method of charge transfer due to limited fringing effect. FIGS. 5A-5C illustrate a very important mechanism called fringe effect which is a charge movement accelerating electrical field caused by the potential difference between adjacent depletion buckets. FIG. 5C is a graph that illustrates the importance of the fringing field. Even in a 4 um process fringing will cause 99.999% of the electrons in a register to transfer within 0.9 ns while only 92% will transfer without fringing in that time.

A formula related to the fringing electrical field of the time it takes to transfer 99.999% of the electrons between adjacent CCD elements in the presence of the fringing field is shown below as Equation 1. A dominant parameter is the length, L, of the elements in the CCD shift register (horizontal axis in the cross sections shown such as FIGS. 5A & 5B). For example, at 40 nm electron transfer is (40n/4000n)³>=1000000× faster than at 4 um, although, there will be a maximum field that can be generated and velocity saturation which will limit these improvements, yet they are still significant. It should also be appreciated that for a digital gate enough charge has to be moved to exceed or be lower than a threshold, usually a number of times, before it will be replenished by a diode.

$${t}_{f} ≃ 0.62 [ \frac{{L}^{3}}{μ {x}_{d} V} ] \cdot {[ \frac{5 \cdot {x}_{d} / L + 1}{5 \cdot {x}_{d} / L} ]}^{4} \qquad ( Eq . 1 ]$$

While there have been advancements in digital design logic and circuits, the ever-increasing need for digital switch based digital implementations (“digital compute”) have further necessitated the need to overcome the inefficiencies of transistor switch-based designs with alternative designs including implementation of novel charge domain digital based designs.

### SUMMARY

A shift register is provided that includes: a silicon fin structure with a series of registers in the form of charge coupled elements positioned along the fin, the series of charge coupled elements defined by one or more of poly gates or metal gates, and where the poly gates or the metal gates are clocked to move charge along the fin.

A shift register device using a single clock is provided in 40 nm or smaller FinFET lithography or planar lithography smaller than 180 nm that includes: a wide n implant, a thin p implant on one side of the n-implant, poly or metal gates on either side of said n-implant, aligned with said n-implant edges, where the gates are further coupled to a clock, a thin p implant under and aligned with the edge of the poly or metal gates furthest away from the n-implant on one side and adjacent to the n-implant but under the other gate on the other side, wherein the p-implant within the well creates a fixed barrier lower than the barrier created by the p implants outside the n-implant (when they are high), and wherein the p implants outside the n-implant create large barriers such that when the clock is high voltage the area under the gate between the p implant the n-implant on one side and the area under the gate on the other side between the p-implant and the other side of the other gate comprise charge coupled elements, and wherein when the gates are low voltage or negative voltage the area under the n-implant outside the p-implant within the n-implant comprises a charge coupled element.

A two-dimensional shift register device is provided that includes: an input charge coupled charge storage element; an output charge coupled charge storage element, a set of horizontal shift registers built upon parallel fins; a first perpendicular (vertical) shift register perpendicular to the set of horizontal shift registers, the first perpendicular shift register accepting input from the input charge coupled charge storage element, and having a first set of storage elements coupled to one side of the horizontal shift registers; a second perpendicular (vertical) shift register having one or more storage elements coupled to another side of the set of horizontal shift registers, where the second perpendicular shift register is further coupled to the output charge storage element; and wherein information is shifted into the shift registers from the input element vertically, and then horizontally as a column through the set of horizontal shift registers, and then vertically into the output element.

A charge actuation device is provided that produces a voltage output upon receipt or removal of an input charge, the charge actuation device includes: an input charge coupled element to accept input charge; a dielectrically neutral spacer coupled to said input charge register; a floating diffusion implanted above the input charge coupled element, the floating diffusion extending over a large portion or all of the dielectrically neutral spacer; a dielectric, such as oxide, layer over the floating diffusion and dielectric; a floating polysilicon layer or metal layer over the portion of said oxide layer that is over the spacer; a reset for periodic reset of said floating polysilicon layer and floating diffusion; and wherein the polysilicon layer is capacitively charged or discharged by moving charge or removing charge from the input charge register and provided to subsequent voltage logic gates for control inputs.

A logic circuit fabricated using charge domain components is provided that includes: one or more voltage input terminals; one or more output charge coupled elements; an input diode, barriers and sink combinations to produce digital logic gate functionality; and wherein the logic circuit is fabricated using a process lithography of less than or equal to 180 nm or a silicon fin equivalent lithography of equal to or less than 40 nm.

A digital logic circuit producing an inverter gate is provided that includes: a notch gate; an output charge coupled element further coupled to the output side of the notch gate; an input diode coupled to an input side of the notch gate; a sink; a barrier coupled between the output charge coupled element and the sink; wherein a common input gate of the barrier and the gate input of the notch gate form a logic voltage control input, such that when a voltage on the logic voltage input is high then the barrier will fall, emptying the output charge coupled element into the sink over the barrier and lowering the notch gate to fill with charge from the diode; and wherein when the voltage on the logic voltage input of the notch gate and barrier is low the barrier will rise blocking the output charge element from the sink and transferring charge to the output charge coupled element.

A charge to barrier control device is provided that includes: an input comprising a charge coupled element; an electrically inert dielectric spacer isolated region; an n+ implant extending from the top of said charge coupled element across all or most of the top of the electrically inert dielectric spacer; a poly layer and dielectric (such as oxide) above said n+ implant; a reset coupled to the n+ implant and poly layer to return their voltage to a reset level; said oxide and poly layer on top of the n+ implant and over the electrically inert dielectric spacer region further extending over silicon on the other side of the spacer from the input charge coupled element for further raising or lowering a barrier in conformance with the charge moved into or out of the input charge coupled element.

A charge to voltage converter is provided that includes: an input charge coupled device (CCD) storage element (charge coupled element); a thyristor n or p base region coupled to the CCD storage element; and wherein a change in charge in the CCD storage element primes or disables the thyristor such that providing a voltage from anode to cathode will turn it on or keep it off, and wherein the charge to voltage converter is fabricated on a semiconductor Fin or in a planar process.

A holdup device to store a logic state includes: an input charge coupled element; a thyristor with a doping level of majority carriers in one of the bases set at a level that is electrically resistant to turn on if an anode to cathode voltage is applied, the base further coupled to the input charge storage element through a dielectric; a control to establish a depletion region of the input charge storage element or a pinning control to permanently maintain the depletion region; and wherein the region of the base closest to the dielectric is reduced in majority carrier concentration with the addition or removal of charge from or to the input charge storage element depending upon the polarity of the base (p or n); and wherein when a voltage from an anode to a cathode of the thyristor is applied to the thyristor in excess of that required for a holding current to be maintained, the thyristor turns on only if the base majority carrier concentration near the dielectric is lowered in conformance with the charge on the charge coupled element.

A device to recover a logic state from a thyristor acting as a digital memory includes: a source of charge; a charge coupled element coupled to said source of charge and coupled through a dielectric to a base of a thyristor, acting as a barrier, and further coupled to an output of a logic gate whose previous state was stored in said thyristor; a control to recreate each of a depletion region of said input charge storage element and said output of said logic gate or a pinning implant to permanently maintain said depletion regions; wherein said logic gate output coupled to said barrier, will be refreshed if its state was previously stored in said thyristor, such that if the base voltage is high and the barrier is then below the level of the source of charge the logic gate output will fill with charge or will remain empty of charge if the base voltage is low (opposite polarity operation may also be engineered if the other base is used).

A memory device includes: a holdup device to store a logic state, the holdup device includes: an input charge coupled element; a thyristor with a doping level of majority carriers in one base set at a level that is not conducive to turn on if an anode to cathode voltage is applied, the base further coupled to the input charge storage element through a dielectric; a control to establish a depletion region of the input charge storage element and/or a pinning implant to permanently maintain the depletion region; and wherein the region of the base closest to the dielectric is reduced in majority carrier concentration with the addition or removal of charge from or to the input charge storage element depending upon the polarity of the base, further called priming; and wherein when a voltage from an anode to a cathode of the thyristor is applied to the thyristor in excess of that required for a holding current to be maintained, said thyristor will turn on only if the base majority carrier concentration near the dielectric is lowered (the thyristor primed) in conformance with the charge on the charge coupled element; and a device to recover a logic state from a thyristor acting as a digital memory, the device includes: a source of charge; a charge coupled element coupled to the source of charge, acting as a barrier, and further coupled through a dielectric to a base of a thyristor; an output charge coupled element; a control to recreate a depletion region of the charge coupled element and output charge coupled element and/or a pinning implant to permanently maintain the depletion region of each of said elements; and wherein a voltage on a base of the thyristor raises or lowers a barrier in the charge coupled element in conformance with whether the thyristor is on and holding or off and thereby provides a path to replenish the output charge coupled element; and wherein the output charge coupled element may constitute a logic gate output whose state was stored in said thyristor; and wherein the memory device further comprises: one or more shift registers coupled to the charge coupled input element used for priming or not priming the thyristor and thereby storing information in the memory device and; one or more shift registers coupled to an output charge coupled element instead for reading information from the memory device; and wherein the memory device allows input to be transferred to and stored or read and recovered from the memory device using the CCD shift register such that the number of contacts is reduced versus a digital transistor switch based static memory bit cell.

A charge domain OR gate device includes: two or more sources of input charge; two or more barriers coupled to the sources of input charge each actuated by a control gate; an output charge coupled element coupled to the two or more barriers; and wherein the barriers falling or rising in conformance with voltage on the control gate will supply charge to the output charge storage element if any of the barriers fall.

A charge domain AND gate device includes: a source of input charge; two or more barriers in series with the source of input charge each actuated by a control gate; an output charge coupled element coupled to the two or more barriers in series; and wherein the output charge coupled element receives charge from the source of input charge which will flow over the fallen barriers after all barriers have fallen in conformance with the voltages on their respective control gates.

A charge domain AND gate device includes: two or more sources of input charge; a common charge coupled element; two or more notch gates each coupled between the two or more sources of input charge and the common charge storage element each further actuated by a control gate; an output charge coupled element coupled to the common charge coupled element by a fixed barrier whose height corresponds to or is below a level that would fill the common charge storage element less the charge associated with the charge that can be stored in one of the charge carrying notches of the notch gates; and wherein the two or more notch gates filling the output charge coupled element only if all notch gates transfer charge to the common charge coupled element producing logic AND functionality.

An OR gate device includes: two or more separate input charge coupled elements; two or more notch gates in series with each of the input charge coupled elements; a common output charge storage element coupled to each of the two or more notch gates such that charge from any notch gate will transfer to the common charge storage element; a set of input control gates, one input control gate over each of the notch gates; and wherein the input control gates cause charge to fill the two or more notch gates and to be transferred to the output charge coupled element in conformance with OR functionality. Charge may either be provided to the input charge coupled elements with all control gates common to a single clock such that the gate is a charge input to charge output gate, or a source of charge may be available to all inputs charge coupled elements and the gate controls independently represent the OR gate inputs producing a voltage to charge output gate.

An XOR gate device includes: two input charge coupled elements containing charge; a set of first barriers with one barrier from the set of first barriers in series with each of the two input charge storage elements; an output charge storage element between the first barriers; two input control gates lowering or raising the barriers in conformance with logic voltage input signals; two second barriers in series with the output charge storage element; two additional control gates lowing or raising the second barriers in conformance with logic voltage inputs signals, each coupled to one of the input control gates; a sink in series with the two second barriers; and wherein if one or the other of the input control gates goes high, then charge will flow into the output charge storage element, however, if both are high then the charge will be sunk into the sink and the output will not contain charge.

An XOR gate device includes: a first input source of charge; a second input source of charge; a first notch gate coupled to the first input source of charge and a second notch gate coupled to the second input source charge, each notch gate also including a control gate to raise or lower each of the notch gates in conformance with a voltage; a first large barrier coupled to the first notch gate and a second large barrier coupled to the second notch gate, where each of the large barriers is capable of completely blocking charge transfer from the notch gates if its respective large barrier is high and allowing charge to flow from each of the notch gates if the large barrier is low, the large barriers also including a control gate to raise or lower each of the large barriers; a single output charge coupled element coupled to both of the large barriers such that either or both of the notch gates can transfer charge to the output charge coupled element provided the large barriers are low; a first drain fixed barrier coupled to the first notch gate, where the height of the fixed barrier is higher than the fixed barrier of the first notch gate, but smaller than the height of the first large barrier; a second drain fixed barrier coupled to the second notch gate, where the height of the fixed barrier is higher than the fixed barrier of the second notch gate, but smaller than the height of the second large barrier; a drain charge coupled element further coupled between the first and second drain fixed barriers; a first reset barrier coupled between said output charge coupled element and a second reset barrier, the first reset barrier also comprising a control gate to raise or lower the barrier in conformance with a voltage; a second reset barrier coupled between the first output barrier and a sink, the barrier also including a control gate to raise or lower the barrier in conformance with a voltage; a third drain barrier coupled between the drain charge coupled element and a second sink; and a fourth drain barrier coupled between the drain charge coupled element and the second sink; and wherein the third drain barrier control gate is further coupled to the first notch control gate, the second large barrier control gate, the first reset barrier control gate and the fourth drain barrier control gate is further coupled to the second notch control gate, the first large barrier control gate, and to the second reset barrier control gate; wherein if the large barriers are high and the notch gates rise then charge will flow over the drain fixed barriers into the drain charge coupled element; wherein if the first input notch control gate voltage goes high and second input notch control gate voltage goes low then the second large barrier will fall allowing the second notch gate to transfer charge to the output charge coupled element and if the second input notch control gate voltage goes high and first input notch control gate voltage goes low then the first large barrier will fall allowing the first notch gate to transfer charge to the output charge coupled element; wherein if both the first and the second notch gate control inputs go low voltage then the charge content of both notch gates will be transferred to the drain charge coupled element and the charge will be blocked from the second sink, however, if the charge from only one notch gate is transferred to the charge coupled element then the drain charge coupled element charge will be immediately drained into the second sink; wherein the input of a charge to barrier device is further coupled to the drain charge coupled element and the barrier is coupled between the output charge coupled element and a third sink such that if there is charge in the drain charge coupled element then the charge to barrier device will transfer the charge in the output charged coupled element to the third sink and leave it empty; and wherein the configuration enabling XOR functionality thereby includes integrated reset functionality.

A charge domain set-reset latch (SR-latch) device includes: a source of charge; a notch gate; a barrier taller than a fixed barrier of the notch gate capable of blocking charge transfer from the notch gate; an output charge coupled element; a first reset barrier and a second reset barrier between the output charge coupled element and a sink; a first logic control input gate controlling the notch gate responsive to a set_bar; a second logic control input gate controlling the taller barrier responsive to a reset_bar; a third logic control input gate controlling the first reset barrier responsive to reset; a fourth logic control input gate controlling the second reset barrier responsive to the set_bar; and wherein logic inputs on the set_bar, reset_bar, and the first reset and the second reset produce or remove charge in the output charge storage element according to SR latch functionality.

A charge domain D latch includes: an input source of charge whose charge levels correspond to a digital 0 or a digital 1; an output charge storage element; a transfer gate transferring the charge to the input charge storage element of a charge controlled barrier device, the charge controlled barrier device being a notch gate coupled to a source of charge; an extended gate coupled to a gate of the charge controlled barrier device actuating a second barrier, the second barrier separating the output charge storage element from a sink; wherein if charge is moved out of the input charge element of the charge controlled barrier device then the notch gate will fall and the notch will fill with charge from the source of charge and the second barrier will fall and direct charge in said output charge storage element to the sink; and wherein if charge is added from the input source of charge then the notch gate will rise and the second barrier will rise, causing the notch gate to spill charge into the output charge storage element and the second barrier to block the output charge storage element from the sink.

A charge domain T-Latch includes: an input source of charge coupled to the output of a charge to barrier device; a charge coupled element coupled to said output barrier and to a reset barrier, the reset barrier controlled by a control gate and further coupled to a sink; an input transfer gate coupled to the charge coupled element and further to a charge to charge device; the output of the charge to charge device further coupled to the input of the charge to barrier device; the n-base of a superjunction thyristor also coupled to the output of the charge to charge device, the superjunction thyristor further coupled to a level shift; the level shift further coupled to the control gate of the reset barrier; wherein if the input to the charge to charge device is initially without charge, then the output of the output barrier between the source of charge and the transfer gate will be low, and the reset barrier will be high causing charge to be available to the transfer gate; and wherein if CK is cycled, then charge will transfer to the input of the charge to charge device, which will add charge to the output of the charge to charge device, causing the barrier of the charge to barrier device to rise, and causing the thyristor to lower the barrier to the sync of the charge coupled element which will remove the charge in the charge coupled element and will disable the prime on the superjunction thyristor, and on the next CK charge will be removed from the input of the charge to charge device which will discharge the output of the charge to charge device and prepare the system for the next toggle.

A charge domain half adder device includes: a first source of input charge and a second source of input charge; a first notch gate coupled to the first source of input charge and a second notch gate coupled to the second source of input charge; a first control gate coupled to the first notch gate and a second control gate coupled to the second notch gate controlling the rise and fall of the notch gates; a sum charge coupled element coupled to the output of both of the notch gates; a fixed barrier whose height is higher than the charge from a single notch of charge but less that of two notches of charge coupled to the sum charge coupled element; a carry charge coupled element coupled to the fixed barrier; a charge to barrier device whose input is coupled to the carry charge coupled element, where the barrier falls if charge enters the carry charge coupled element; and the barrier of the charge to barrier device is further coupled to a sink; wherein if only one input transfer charge to the sum charge coupled element, then the charge represents an output ‘1’, however, if both charge coupled elements transfer charge then the carry will contain charge, representing a ‘1’ and the charge in the summing charge coupled element will be removed representing a ‘0’ thus producing half adder functionality.

A charge domain full adder device includes: three or more two input notch based AND gates coupled to a common sum charge coupled element each through a fixed barrier, the barrier taller than a single packet of notch charge but less than two notch charges; a carry fixed barrier higher than a single notch of charge but less than two notches of charge coupled to the sum charge coupled element; a carry charge coupled element coupled to the carry barrier, the carry charge storage element coupled to a first charge to barrier lowering device to lower the barrier if charge is present in said carry charge coupled element, said first charge to barrier lowering device lowering a barrier between the sum charge storage element and a sink which has limited sinking capability; a second barrier coupled to the sum charge coupled element taller than a single packet of notch charge but less than two notch charges; said barrier further coupled to a second charge to barrier lowering device such that if charge flows over said second barrier, said second charge to barrier lowering device lowers a barrier between the sum charge element and a source of charge such that the sum charge storage element is filled to or just below the carry charge barrier level, where the first charge to barrier device is delayed such that the second charge to barrier device will actuate before the second charge to barrier device, if charge flows over the second fixed barrier, ensuring that the charge will not be removed in said sum charge storage element in the case of the carry element being full and charge also flowing over said second fixed barrier. The charge to barrier devices could be a thyristor coupled to the gate of a charge coupled element, where said charge coupled element is acting is a barrier.

A charge domain multiplier device includes: two input shift registers each containing a binary number; a control responsive to the vedic algorithm; a set of AND gates coupled to the shift registers; and wherein the numbers in the two input shift registers are shifted and ANDed according to the vedic algorithm to multiply the two binary numbers.

A charge domain memory page includes: a Fin; two or more holdup cells; a horizontal CCD shift register to shift information to or from said holdup cells; vertical shift registers to shift information from the horizontal shift register into the write side of said holding register and out of the read side of said holdup cells into said horizontal shift register and wherein the memory page device is distributed along the Fin and information stored and recovered using the horizontal CCD shift register, avoiding the need for large numbers of contacts across multiple bitcells and to form a memory array.

A dual CCD shift register page device includes: a Fin; and one or more MOS capacitors with poly separated at the top of the Fin to form two vertical depletion MOS capacitors.

A holdup cell includes: a Fin; a CCD shift register fabricated on one side of the Fin; a vertical thyristor fabricated on the other side of a fin; and a vertical dielectric to separate CCD register elements from abase region of the thyristor. A memory page contains one or more holdup cell devices.

A DRAM page includes: one or more rows of CCD shift registers each of the CCD shift registers having gates, the gates of the shift registers being common stripes connected to control gates which are further coupled to a control; two columns of CCD shift registers having gates; an input terminal; an output terminal; and wherein each of the one or more rows of CCD shift registers is coupled to a first common column shift register on one side for accepting and shifting input charge; wherein gates of the column shift register are coupled to a column gate control; wherein each of the rows are coupled to a second common column shift register on the side opposite side from the first common column shift register; wherein the first shift register is coupled to the input terminal; wherein the second shift register is coupled to the output terminal; and wherein digital information is clocked into the shift register as a high charge or low charge from said input terminal, first vertically on the first column shift register, then horizontally across the parallel row shift registers, and finally vertically again with the second shift register to the output terminal in conformance with gate control on the control gates; and wherein the DRAM is further fabricated on less than 180 nm lithography or 40 nm FinFET equivalent gate lithography process or less;

A dynamic charge domain logic gate converted to a static gate by coupling an output of the dynamic charge domain logic gate to a holdup cell or memory page device, where the holdup cell or memory page device refreshes said logic gate in conformance with a control command or a control command is generated in conformance with an input change within the logic algorithm of which the logic gate is a part.

A reset device coupled to charge coupled elements of a charge domain gate, further coupled to a reset signal, where the reset signal removes the charge from the charge coupled elements by sinking charge through one or more barriers to one or more sinks.

A charge actuated driver device includes; a thyristor base coupled to a charge coupled element through a dielectric; and wherein priming of the thyristor is by adding or removing charge to or from the charge coupled element, where said thyristor further couples the voltage source to a load, which are one or more of capacitances of on chip metal lines, capacitors, resistors, or other loads, or an off-chip load.

Charge domain digital logic gates incorporated into a standard digital flow such that front end design only requires changes to timing and the backend takes care of register-transfer level (RTL) and polygon placement using charge domain devices intermixed with transistor switch based devices or only charge domain digital logic gates.

A charge replicator device comprising: an input diode into which charge might be moved; a separate diode coupled to a barrier, where the gate control input of the barrier is coupled by a wire to the input diode, causing the barrier height to be proportional to the charge input into the input diode, said separate diode further having a wire connection to raise or low the charge level under the separate diode; a charge coupled element coupled to the other side of the barrier; and wherein a voltage on said separate diode cathode is lowered and then raised to cycle charge higher than the highest expected barrier height and then below the lowest expected level of the barrier such that the charge coupled element is filled with charge to the level of the barrier, the charge constituting a replicated charge.

### BRIEF DESCRIPTION OF THE DRAWINGS

The present invention is further detailed with respect to the following drawings that are intended to show certain aspects of the present invention, but should not be construed as a limit on the practice of the present invention.

FIGS. 1A and 1B are schematic diagrams of the most basic element of charge domain processing which is the transient depletion metal oxide semiconductor (MOS) capacitor formed after a change in gate voltage above a charge coupled element or statically created by an implant (pinning) or a combination thereof,

FIGS. 2A-2E illustrate movement of charge along a charge coupled device (CCD) shift register;

FIG. 3A shows a diode formed by implanting an n+ region and coupling that n+ region to voltage Vin as a source of input charge for a charge domain circuit;

FIG. 3B shows the movement charge from the diode of FIG. 3A through a charge coupled shift register;

FIG. 3C is a timing diagram showing the voltages placed upon the gates to move the charge through the charge coupled shift register in FIG. 3B;

FIG. 4 shows an AND gate from the 1970's fabricated with 5 um technology;

FIGS. 5A-5C illustrate the fringe effect mechanism which is an electrical field caused by the potential difference between adjacent depletion buckets;

FIG. 6 is a depiction of charge couple device (CCD) shift registers built on a below or equal to 40 nm equivalent FinFET process where the shift register is built on a Fin;

FIG. 7 is a schematic of a shift register built using flip flops;

FIG. 8A is a transistor switch-based implementation of a flip flop;

FIG. 8B is an example of a FinFET similar to that which may be used for the transistor switches in a flip flop;

FIG. 9 is an exemplary CCD shift register built on a Fin in technology computer-aided design (TCAD) Sentaurus;

FIG. 10 is a diagram showing the movement of charge through the shift register in time;

FIG. 11 is an alternative shift register structure that reduces the number of cycles needed to move and isolate charge and which uses a single clock;

FIGS. 12A-12D illustrate the use of notch gates between CCD storage elements;

FIG. 13 illustrates a superjunction reader in a dashed box that accepts charge as an input and raises or lowers a barrier as an output;

FIG. 14 is a schematic of a CCD coupled thyristor;

FIG. 15 illustrates vertical and planar designs of a Fin thyristor;

FIG. 16 is circuit schematic representation of the Fin thyristor used in the vertical and planar designs of FIG. 15 as well as a supply to its anode and resistive and capacitive load and a reset switch;

FIG. 17A-17D illustrate additional FinFET configurations for a Fin thyristor;

FIG. 18 shows the equivalent circuit of a thyristor with an input gate terminal which can be capacitively coupled to a base;

FIGS. 19A and 19B show the use of superjunction to change the effective base doping in a portion of the FinFET structure to allow or disable its function when an anode voltage is applied;

FIG. 20 shows the minority carrier concentrations in the three regions of the npn at the bottom of the thyristor to illustrate the importance of low doping concentration throughout the base region to allow minority carriers to diffuse and draft from emitter to collector;

FIGS. 21A, 21B, 21C, 21D, 21E and 21F illustrate the superjunction concept that may be used with the CCD charge element by isolating with a thin vertical insulator between the CCD charge element and the base of the thyristor;

FIGS. 21B and 21C illustrate a holdup cell using the p-base for writing and reading, respectively, as well as illustrating charge distributions in the base and relative equivalent doping to disable or prime thyristor functionality;

FIGS. 21D and 21E illustrate holdup cells with write functionality and read functionality, respectively, to and from the holdup cell using the n-base to write and the p-base to read, where diode level shifts are further illustrated if the p-base needs to be higher in voltage for read;

FIG. 21F illustrates a shift register using holdup cells with read and write capability further coupled to a CCD shift register

FIGS. 22A-22D show the operation of the superjunction in more detail;

FIG. 23 is an electropotential plot of the thyristor base region as the charge in the charge coupled element coupled to said thyristor base region is changed;

FIG. 24 illustrates an implementation of the superjunction as a solution to the prior art deficiency of being unable to accept an input charge as an input control;

FIG. 25A is a transistor switched based implementation of an AND gate;

FIG. 25B is a simple barrier based AND gate where inputs are A and B on the gates of the barriers, a diode is used for a source of charge and the output is on the right with full of charge being a ‘1’ and empty of charge being a zero, where in operation charge from the diode is blocked from entering the output until both A and B are high voltage so that the barriers can fall;

FIG. 26 is an AND gate with pinned charge storage elements with a depletion region bottom being lower with each stage to allow higher speed operation due to the fringe effect;

FIG. 27 is a notch gate-based implementation of an AND gate;

FIG. 28 is a simple OR gate with two barriers and an output charge node in the center;

FIG. 29 is a notch gate implementation of an OR gate;

FIG. 30 shows a block diagram of the functionality including two notch gates, an output memory node (MN) charge storage element to hold the OR output, a barrier and an AND output charge storage element, where this configuration can achieve both AND and OR functionality;

FIG. 31 shows the cross section of a construction that realizes both an OR functionality and an AND functionality;

FIG. 32 shows a notch gate implementation that creates both OR and AND functionality;

FIG. 33 is an exclusive-or (XOR) gate construction;

FIG. 34 is a notch based XOR which does not require an external reset;

FIG. 35 is an inverter gate;

FIGS. 36A-36D illustrate the operation of a charge domain set-reset latch (SR-latch);

FIG. 37 is a block diagram of a data latch (D-latch);

FIG. 38 is a circuit schematic of a D-latch;

FIG. 39 shows a charge domain implementation of a D-Latch;

FIG. 40 is a block diagram of a toggle flip flop or T-latch;

FIGS. 41A and 41B are an implementation of a toggle flip flop in the charge domain;

FIG. 42 shows a block diagram of a half adder charge domain block;

FIG. 43 shows an implementation of a half adder charge domain block using notch gates and a thyristor, as well as a capacitor reservoir source of charge (Vb);

FIG. 44 shows a 6-input full adder;

FIG. 45 shows the steps required such that the lines request the AND operations in this case to multiply two six bit numbers with a vedic multiplier;

FIG. 46 shows a shift register for moving the coefficients around such that they are available for vedic operation;

FIGS. 47A and 47B illustrate a circuit schematic and basic bit cell in 5 nm lithography, respectively, for charge domain static memory;

FIG. 48 shows the layout for a dual FinFET inverter;

FIG. 49 shows a two-sided depletion region on a fin with top poly cut to maximize electron storage;

FIG. 50 shows a two-dimensional CCD shift register built on Fins;

FIG. 51 shows an exemplary two-dimensional shift register;

FIG. 52 shows an exemplary two-dimensional shift register using notch gates, as well as an output to input coupling illustrating cyclic refresh;

FIG. 53 shows a two-dimensional shift register which is reduced in size using the structure of FIG. 11;

FIGS. 54A-54H show the movement of binary information through the two-dimensional shift register of FIG. 53, where ‘0’ means no charge and ‘1’ means charge;

FIG. 55 is an exemplary description of a notch based two-dimensional shift register cycling information through the shift register and back to the input, teaching cyclic refresh;

FIG. 56 shows an exemplary two-dimensional shift register of FIG. 53 further including a shift register to return the output value to the input of the shift register for cyclic refresh;

FIG. 57 shows a Sentaurus TAD three-dimensional view of a planar two-dimensional shift register;

FIG. 58 shows a Sentaurus TCAD potential plot illustrating operation of the notch gate;

FIG. 59 shows an exemplary thyristor further coupled to a charge coupled element through a dielectric, where the charge coupled element is further coupled to a diode through a transfer gate;

FIG. 60A shows a two-dimensional shift register with an output to input shift register charge to barrier device to implement cyclic refresh;

FIG. 60B shows four exemplary methods to return the output of the two-dimensional shift register of FIG. 60A to its input to cyclic refresh;

FIG. 61 shows a five element Fin based shift register in 40 nm or less FinFET gate lithography;

FIG. 62 shows the charge moving through the Fin based shift register of FIG. 9;

FIG. 63 shows an exemplary charge level plot indicating a ‘1’ region above a threshold and a ‘0’ region below a threshold and with an undefined region in between for using charge as an binary indicator; and

FIG. 64 shows an exemplary charge replicator which can be used for example to copy the charge at the output of a two-dimensional shift register to a second charge coupled shift register which could be the input to the two-dimensional shift register.

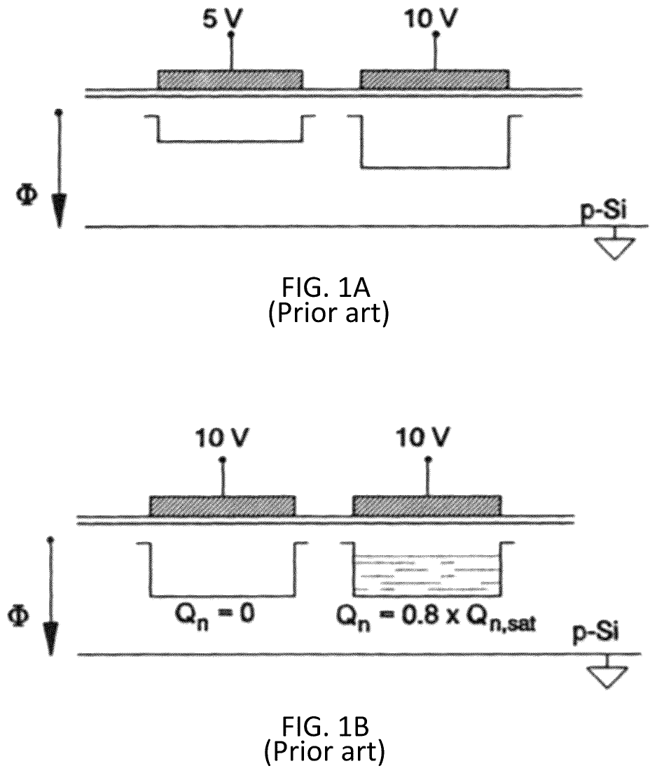

It is understood that like reference characters refer to like elements throughout the several figures.

### DETAILED DESCRIPTION

Embodiments of the invention provide methods and structures by which the limitations charge domain digital based designs can for the first time be overcome; allowing charge domain digital to regain its position as the leading method for digital circuit implementation.

The present invention will now be described with reference to the following embodiments. As is apparent by these descriptions, this invention can be embodied in different forms and should not be construed as limited to the embodiments set forth herein. Rather, these embodiments are provided so that this disclosure will be thorough and complete and will fully convey the scope of the invention to those skilled in the art. For example, features illustrated with respect to one embodiment can be incorporated into other embodiments, and features illustrated with respect to a particular embodiment may be deleted from the embodiment. In addition, numerous variations and additions to the embodiments suggested herein will be apparent to those skilled in the art in light of the instant disclosure, which does not depart from the instant invention. Hence, the following specification is intended to illustrate some particular embodiments of the invention and not to exhaustively specify all permutations, combinations, and variations thereof.

It is to be understood that in instances where a range of values is provided, the range is intended to encompass not only the endpoint values of the range but also intermediate values of the range as explicitly being included within the range and varying by the last significant figure of the range. By way of example, a recited range of from 1 to 4 is intended to include 1-2, 1-3, 2-4, 3-4, and 1-4.

Unless otherwise defined, all technical and scientific terms used herein have the same meaning as commonly understood by one of ordinary skill in the art to which this invention belongs. The terminology used in the description of the invention herein is for the purpose of describing particular embodiments only and is not intended to be limiting of the invention.

Unless indicated otherwise, explicitly or by context, the following terms are used herein as set forth below.

As used in the description of the invention and the appended claims, the singular forms “a,” “an” and “the” are intended to include the plural forms as well, unless the context clearly indicates otherwise.

Also as used herein, “and/of” refers to and encompasses any and all possible combinations of one or more of the associated listed items, as well as the lack of combinations when interpreted in the alternative (“or”).

### CCD Shift Registers Below 180 nm and on 40 nm or Smaller FinFET Process

If a Fin is used the device geometry generally tends to be even smaller. A Fin based CCD shift register is shown in FIG. 6. The wrap around gate coupled with the small lithography allows for extremely fast transfer of charge across the shift register. As will be disclosed herein in embodiments of the invention, there is a capacitive effect that can be taken advantage of to move charge between the CCD elements that overcomes the need for overlapping gates at these dimensions if the structure is properly constructed. This is an advantage as overlapping gates are difficult to fabricate upon a Fin and are not standard. At the smallest lithographies such as 2 nm the increase in transfer speed is even more profound compared to older geometries. Embodiments disclosed herein teach smaller than 180 nm planar and 40 nm or smaller equivalent Fin shift registers and logic gates with these advantages.

FIG. 7 is a schematic of a shift register. A shift register accepts a binary input and moves it along the string of flip flops with each shift.

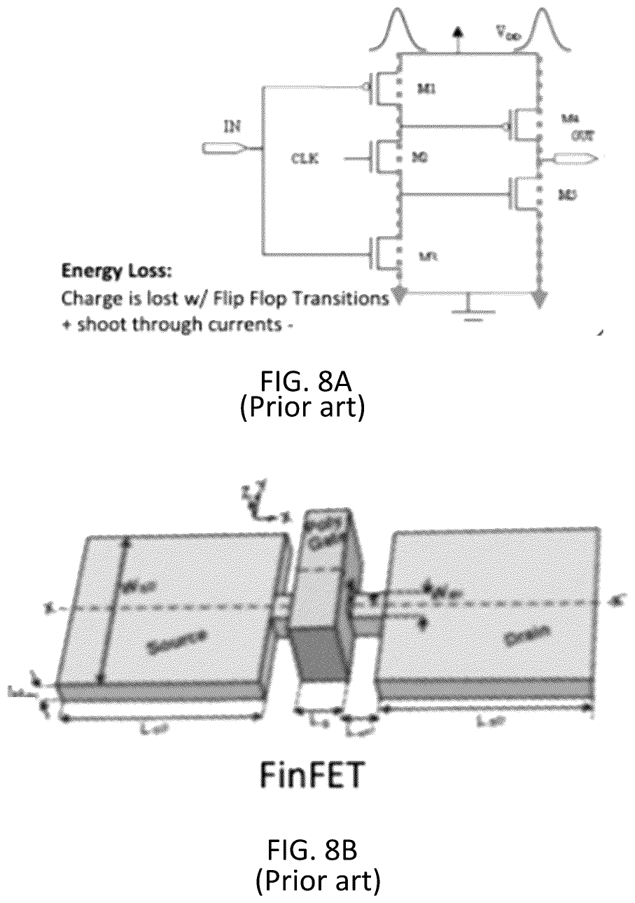

FIG. 8A is a transistor switch-based implementation of a flip flop. It is appreciated that each of the flip flops in FIG. 7 requires five transistors, two of which are pchannel located in their own n well which takes up space. During operation flip flops will produce an output that matches the input when clocked, however, during that time charge is flushed if the previous output value was a ‘1’ and charged if it was a ‘0’. The red pulses indicate a charge shoot through current that wastes power and causes glitches on the power supply lines as the pchannel devices turn on and the n-channel devices turn on and vice versa. In FIG. 8B a FinFET is depicted that may be used as transistor switches in the flip flops. Note that although the gate length is small on the FinFET, that the drain and source regions are large. The flip flops additionally have the downside of a number of overlap and other parasitic capacitances that must be charged and flushed as the flip flop transitions from a ‘1’ to a ‘0’ or a ‘0’ to a ‘1’. The march across the flip flops of an input value is actually not movement but rather a flushing and charging of each flip flop in turn depending upon the value from the previous register. Additionally, with each transition there is a period of time where both transistor switches are on and there is a direct path from the supply to ground. This wastes significant power. Finally, the close proximity of the source and drain regions causes significant leakage and also gate induced barrier lowering (Vt changing) during operation.

Considering FIG. 6 again, it may be seen that it is possible to fit multiple CCD charge storage elements (gates around the fin) in the same area as a single FinFET if the drain and source are removed and the space used to extend the Fin. This means that in the example thirty CCD elements may be fit in the same area as a single flip flop by replacing each FinFET with six CCD elements and a longer Fin. Additionally, the charge is being moved along the Fin rather than flushing and replenishing as in the FinFET case, and the capacitance associated with the drain and source regions, which slows down commutation and wastes power, has been reduced. Finally, it is no longer necessary to bear the glitches and power losses associated with shoot through currents as in the transistor switch case as the charge is actually moving along the Fin.

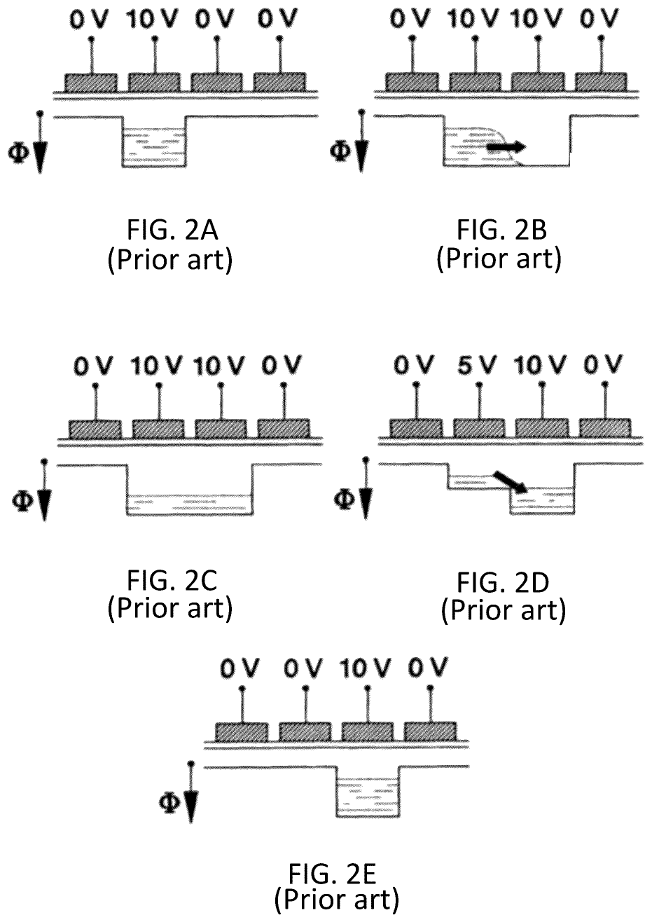

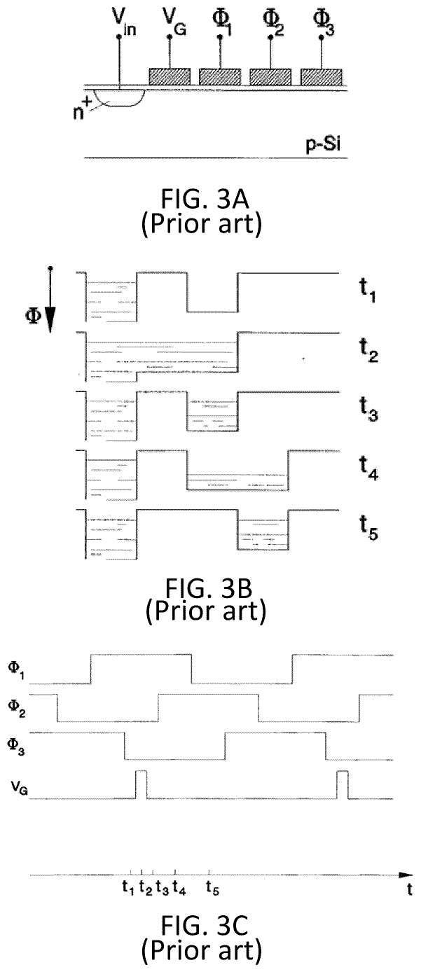

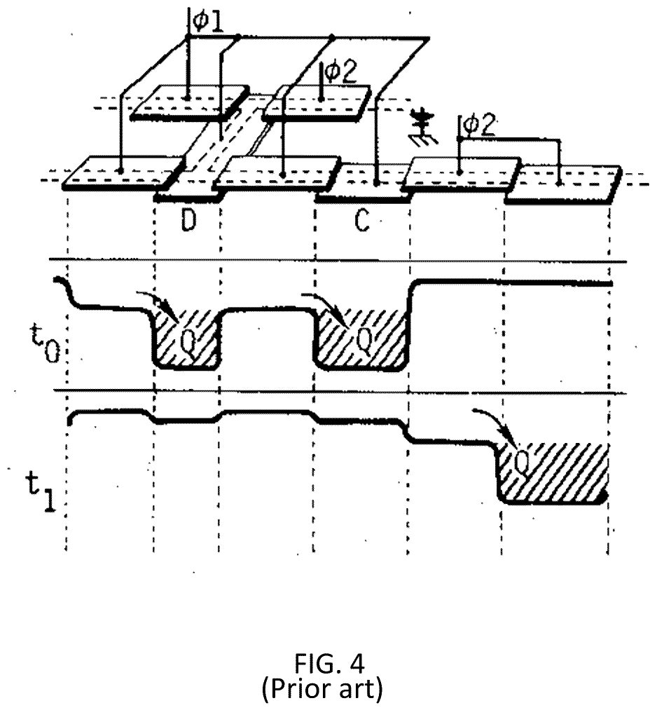

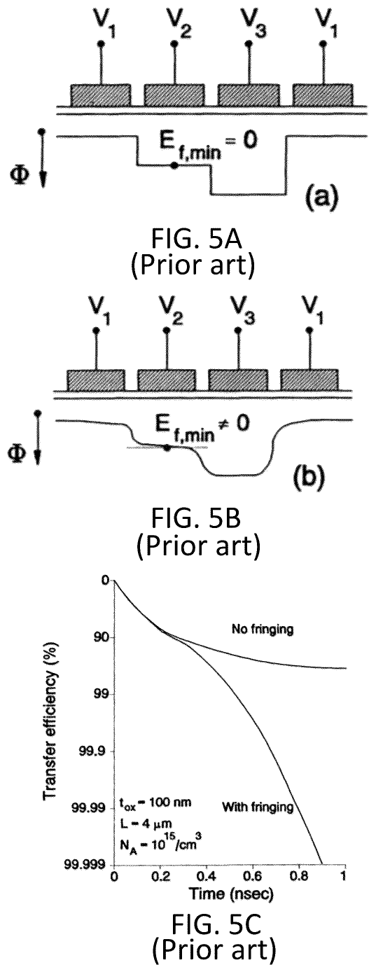

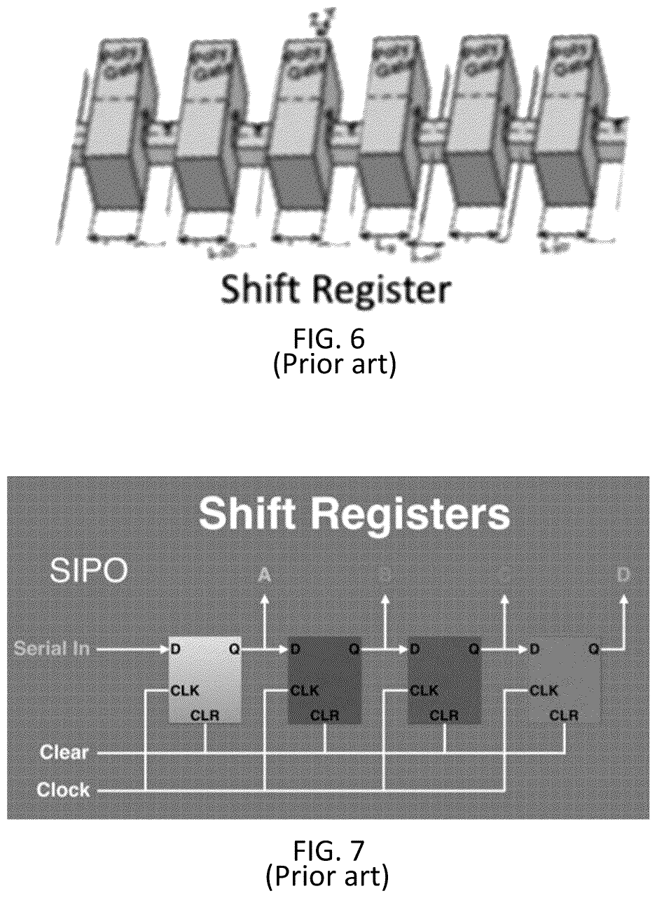

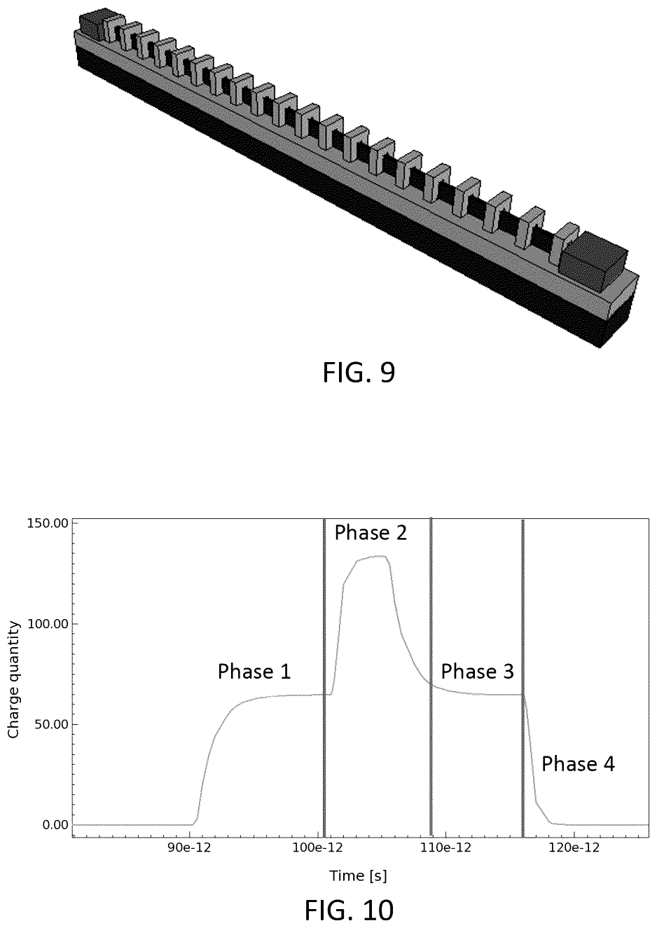

FIG. 9 shows an exemplary CCD shift register built on a Fin. FIG. 10 shows the charge transfer between gates in time in the FinFET shift register in FIG. 9 using a mechanism similar to that illustrated in FIG. 2. For each element filled with charge it takes multiple cycles to move and isolate the charge in the next CCD element. In Phase 1 the gate voltage on the element is raised and charge from the previous element is shared. In Phase2 the previous element gate is turned off and its charge transfers to the current element. The charge is isolated and has effectively been moved from the previous element. In Phase3 the following element gate is raised and the charge is shared with the current element. In Phase4 the gate is lowered on the current element and charge is transferred to the next element leaving it discharged. It therefore takes two cycles to completely move charge from one element to the next and the forces doing so are capacitive coupling, diffusion, and drift with minimal fringe effect in this example.

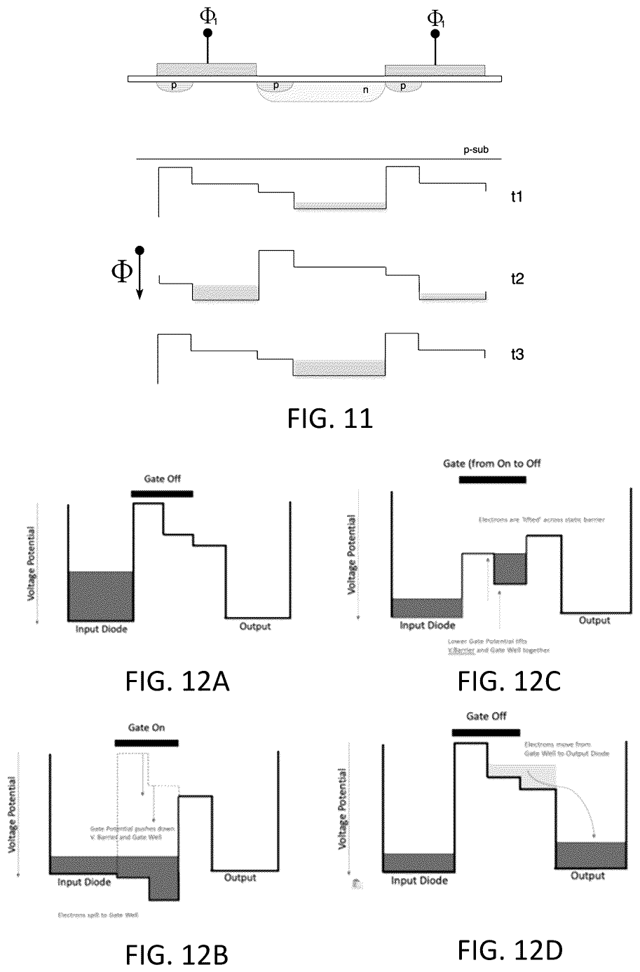

There are other methods by which to reduce the number of cycles needed to move and isolate charge as further shown in FIG. 11. In this case overlapping implants are used to create additional small barriers and pinned wells such that charge can be moved with a single clock without having to use the larger charge coupled elements for isolation as in FIG. 10.

An improvement to the shift register of FIG. 9 is to use the notch gate in FIGS. 12A-12D between CCD storage elements rather than a single gate structure. The notch gate is built on the Fin by using two implants. Assuming a p-substrate the leftmost implant of the notch gate is intrinsic or p+ doped such that it has the highest barrier when off (no voltage or negative voltage on gate). The implant to its right is an n implant meant to build in a potential drop to create a notch with a potential lower than the well bottom of the left barrier when on. The rightmost implant is a more highly doped n implant meant to maintain a barrier that does not reach the potential of either of the other implants when the other two are off (but is fixed and not gated). The gate covers the two leftmost implants such that they may be raised or lowered. When raised, the three barriers look like a succession of potential steps as per FIG. 12A. In FIGS. 12A-12D operation is shown. In FIG. 12A the gate voltage is low, the barriers are up and charge from an input diode to the left of the notch gate is blocked by the leftmost barrier. In FIG. 12B the gate voltage is high, the barriers fall, and charge from the input diode fills the notch and the area above the leftmost barrier but is blocked by the fixed barrier. In FIG. 12C the gate is turned off (voltage low) and the two leftmost barriers start to rise. The leftmost barrier rises at the same rate as the lower notch and therefore the charge in the notch is blocked and lifted until in FIG. 12D the charge potential in the notch exceeds that of the fixed barrier and starts spilling charge into the output charge coupled element element. The length of the notch gate relative to a single poly gate is 50% larger than the poly gate if implants can be deposited on the Fin with finer precision than the poly, but it is not necessary to have two full gates to isolate as in the simple CCD case. This is a marginal increase in width (e.g., 3 nm gate would be 4.5 nm) relative to the benefits. The benefits are: i) limiting the charge that is transferred saving power and increasing speed by reducing the number of electrons that have to be transferred ii) taking advantage of the fringe effect by lifting the charge rather than relying only on diffusion, drift, and capacitive coupling increasing transfer speed significantly iii) reducing the leakage or jumping of electrons between bins by adding a wider barrier iv) doubling or more the effective clock rate and simplifying clocking

### Charge to Voltage Conversion

One of the primary deficiencies of the prior art is the inability to convert charge to voltage. The AND gate in FIG. 4 produces a charge output, however, to convert that charge to voltage or a way to use that charge in a subsequent gate is required. The bandwidth limiting op amp circuit used in the past, and the resulting speed and area required to implement it is prohibitive. Embodiments of the invention provide two mechanisms to overcome this limitation: i) the charge domain superjunction (SJ) reader, and ii) the superjunction (SJ) thyristor reader.

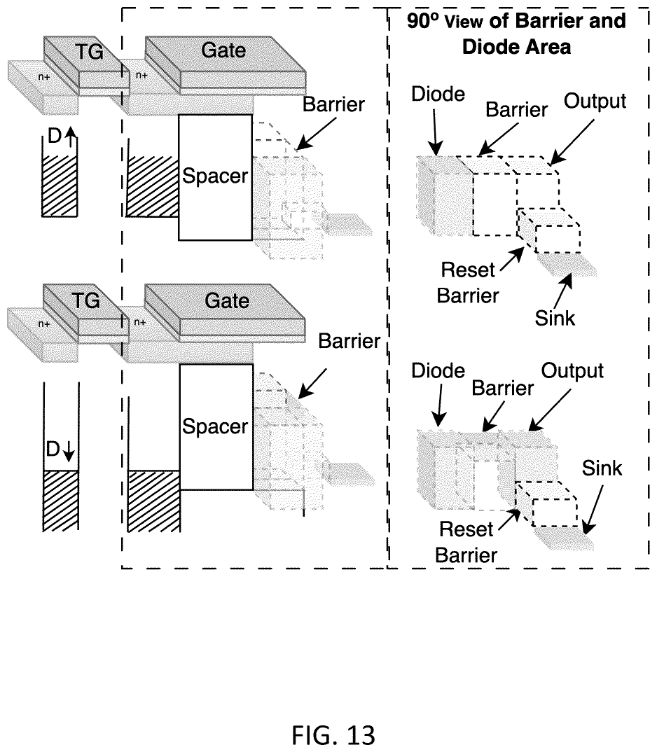

The first mechanism is the superjunction reader, shown in FIG. 13 in the dashed box, which capacitively couples the change in voltage when charge is moved under a floating diffusion and a floating gate to further raise or lower a barrier. The circuitry outside the dashed box is to move charge under the left side (charge input element) of the floating diffusion (n+) within the dashed box and could be the output of a previous gate or other source of charge. The presence of a CK (clock) node to move the charge is not a requirement of the superjunction reader and is shown as one example of transferring charge into the superjunction reader. The output barrier has an input diode on one side reaching the top of the barrier, and an output charge storage element on the other (looking into the page) such that if this mechanism lowers the barrier even by a small amount, then the charge storage element will charge up with a large amount of charge. The charge storage element may not have significant voltage variation if the amount of charge moved under it the n+ input charge coupled element is small. This voltage change will further couple onto the poly gate through the oxide, where said poly gate and oxide region is be extended over another silicon area to raise or lower a barrier but only by a small amount. Nevertheless, if a diode charge level is just below the top of the barrier then even the small drop in barrier height will fill the output element. This arrangement is in fact acting like a charge amplifier by converting even a small charge change to a small barrier drop, but then on the output to a full well charge. This also provides a refresh mechanism between logic gates. It is also possible that the poly or n+ can be extended to other gates or coupled to metal and the metal used for downstream voltage control such as connecting to the gates of other charge coupled elements.

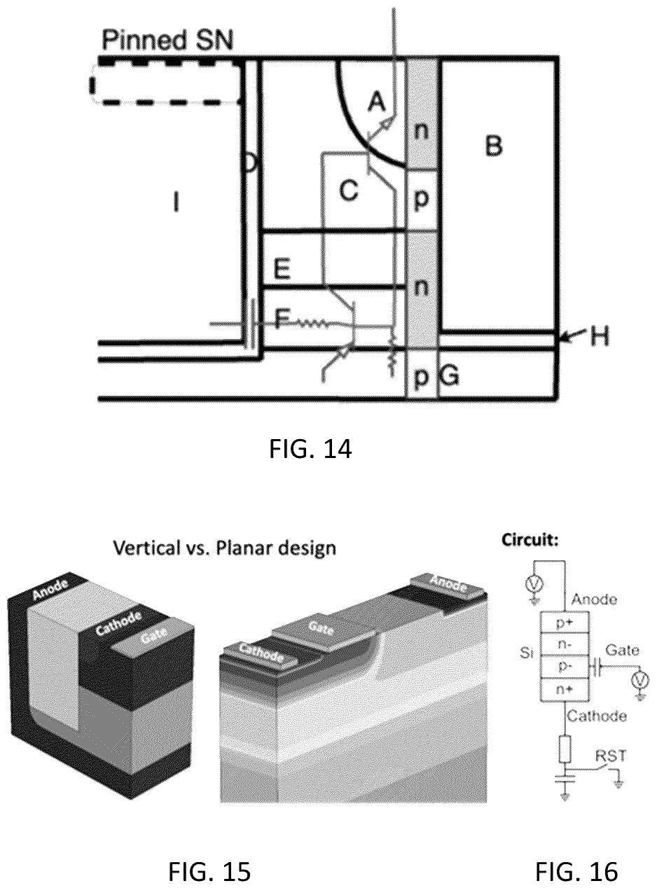

FIG. 14 shows a CCD coupled thyristor. On the left is a pinned or unpinned charge input coupled element surrounded by an insulating layer. Adding or removing charge from this layer can be used to trigger a thyristor either through a capacitive injection or through the superjunction method described earlier. If the thyristor output is coupled to a voltage gate it may be used to raise or lower the voltage to actuate voltage-controlled gates and their barriers of downstream logic in response to charge entering the input charge coupled element. The thyristor may also be used as a driver when large metal capacitances or off device drivers are needed. The thyristor can be created in an area 50% larger than a standard FinFET gate and therefore is not an expensive device even if it were required on every gate.

### Fin Thyristor

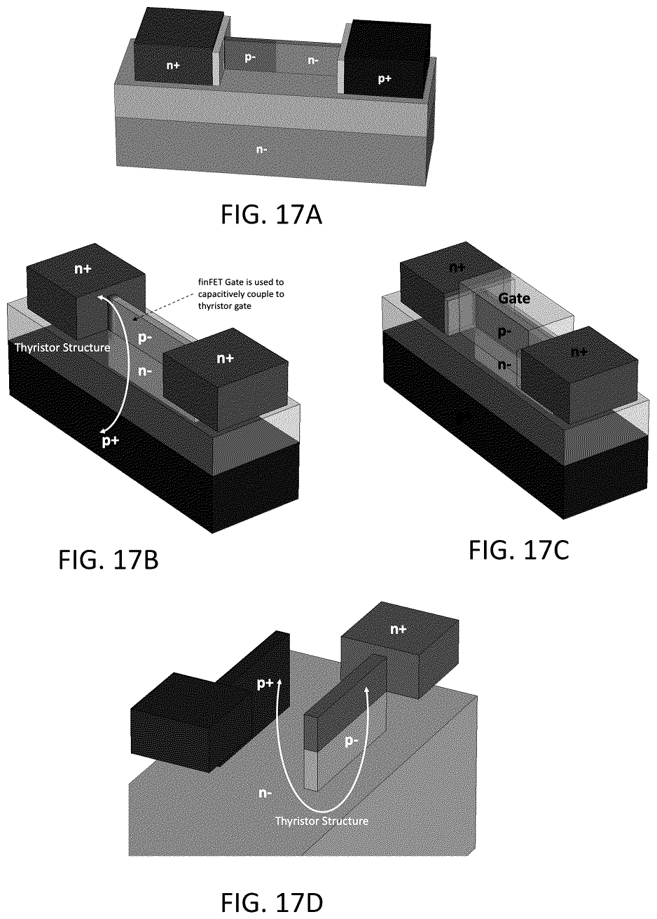

FIG. 15 shows the concept of a Fin thyristor in a vertical and planar design that can be used for charge to voltage conversion as well as for static logic implementation. Although the gate terminal is labelled in FIG. 15, the terminal connection can be removed and instead a vertical thin isolation and a CCD storage element can be placed beside it to the implement actuation functionality using either charge injection or the superjunction method. The schematic of FIG. 16 further illustrates the thyristor in series with a resistance representing a wire to coupling to a gate and the capacitor represents a logic gate input poly gate. This illustrates how the thyristor can convert a CCD charge input to a voltage that is used to actuate a poly gate. FIGS. 17A-17D show some additional Fin based thyristor configurations that could be used.

### Superjunction Thyristor Control

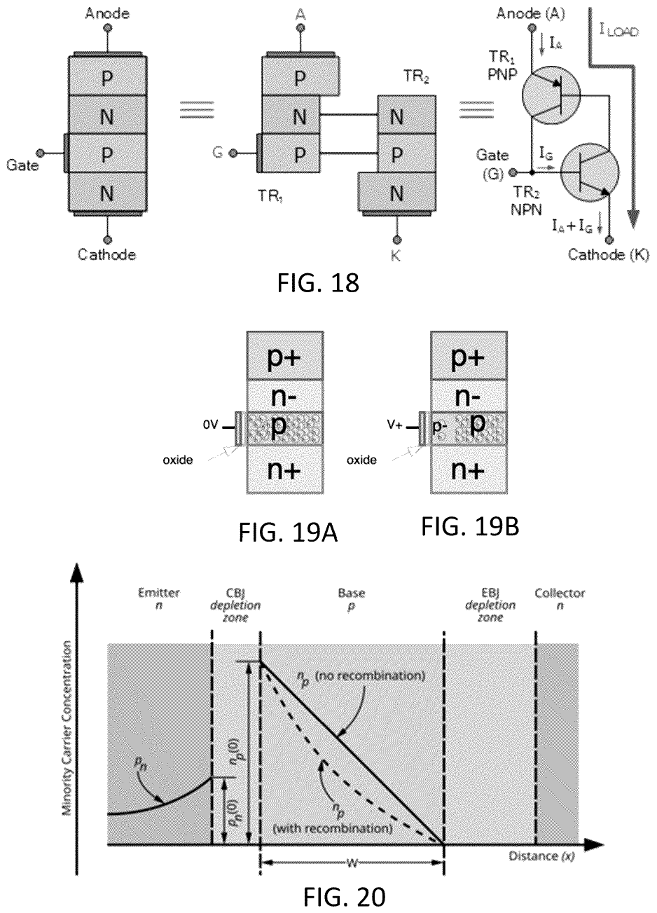

FIG. 18 shows the equivalent circuit of a thyristor with a contact input gate terminal which can be used to inject a current to strike the thyristor. If instead a dielectric is used, such as oxide, this injection is now effectively capacitively coupled. The superjunction method occurs if the doping concentration is increased in the base such that the oxide is not used for capacitive coupling of an injection current but instead is used to push majority carriers away and pull minority carriers close to the oxide, which is called priming the thyristor. This effectively reduces the majority carrier concentration in the base next to the oxide for the purpose of creating a local thyristor path. Thereafter, when a voltage is placed across the anode to cathode it will turn on depending upon whether the thyristor is primed or not. If the high doping concentration is chosen properly, the thyristor will stay on regardless of the state of the charge coupled element on the other side of the oxide from the thyristor base as the thyristor structure can supply needed base minority carriers once established at a level that the initial turn on process cannot. This method overcomes the risk of false trigger of the thyristor if we use a capacitively coupled gate or directly inject charge. The superjunction method is illustrated graphically in FIGS. 19A and 19B. As shown in FIG. 19A, when the gate voltage is low, the holes will distribute throughout the p-base region, however, with the p-base region doped higher than normal such that the gain of the npn is too low to trigger the positive feedback structure if a transient were to enter either of the bases or voltage were to be stepped across Vce. In FIG. 19B a voltage is put on gate of the horizontal MOS capacitor structure. This voltage will push away positive carriers and attract negative carriers, and leave a more lightly doped area on the left side of the MOS capacitor closest to the oxide. At this point the small area just to the right of the oxide will have a lower concentration creating a new “mini” bipolar transistor with a higher beta gain along the left side of the structure. If a Vce is put across this structure it would turn on the thyristor structure and could for example hold or charge up a control gate and turn off once the control gate is full. Once this smaller bipolar transistor is turned on it will also cause the rest of the bipolar (base) to turn on once the collector current is established to replenish even a low gain npn, and the thyristor will hold even if the positive voltage on the gate is taken away. If instead of voltage a charge coupled element is put on the side of the oxide away from the thyristor then the charge in the charge coupled element will act similarly to the voltage on the vertical gate in allowing or disabling superjunction operation (priming).

FIG. 20 shows the minority carrier concentrations in the three regions of the npn at the bottom of the thyristor. For the npn beta to be high enough for the thyristor to turn on, the base must be thin and lightly doped. Instead, in the superjunction thyristor the natural doping concentration is purposely made too high to allow turn on of the thyristor unless a voltage is applied statically on the other side of the oxide, either directly or by putting or removing charge into or from a charge coupled element, to temporarily create a higher beta base structure. Either the npn or pnp can be used with opposite voltages or charges required to prime the thyristor. For example, for an npn, removing charge from a charge storage element next to a thin dielectric coupled on the other side to the npn base will create the lower doped npn base with higher beta, while for the pnp, adding charge would do so.

It is important to note that with the superjunction structure the thyristor is not actuated with current directly or capacitively injected into the base as in other conventional structures. In the superjunction case once the thyristor is primed to form a parallel thyristor structure, a bipolar gain on the base that is capable of providing thyristor turn on action is formed, such that applying a cathode to emitter voltage commensurate with one bipolar vbe+vce (collector to emitter) will cause the device to latch on. Even if the voltage or charge that caused the initial priming is removed the thyristor will stay on until the anode to cathode voltage drops too low or current is interrupted, for example once a capacitive element it is charging has become fully charged.

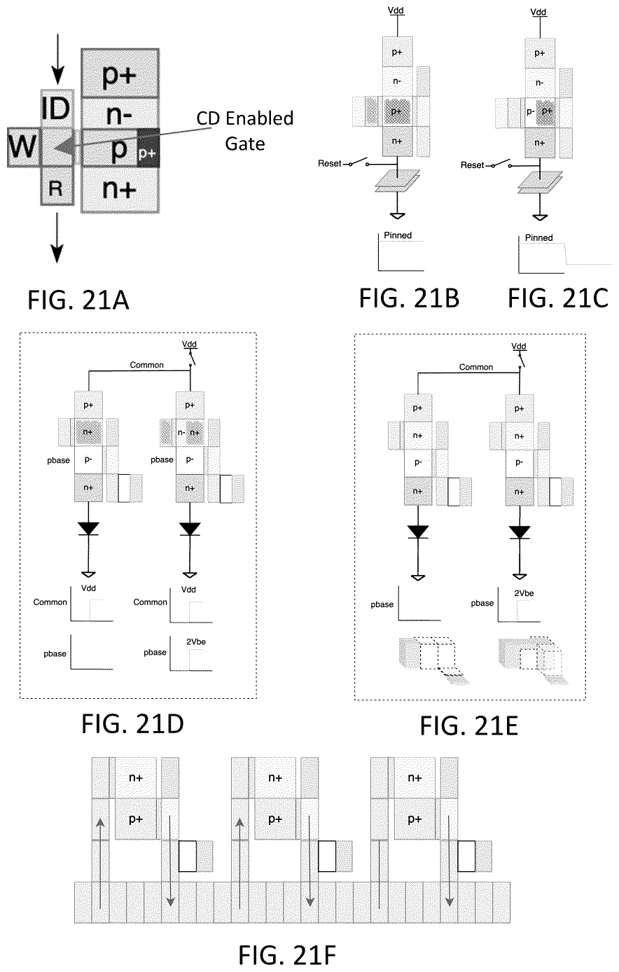

The superjunction concept may be used with the CCD charge element by isolating with a thin vertical insulator between the CCD charge element and the base of the thyristor as illustrated in FIGS. 21A, 21B, 21C, 21D, 21E and 21F. The thyristor cannot turn on with a controlled increase in voltage from anode to cathode as the doping of the base is made to be too high for the available injection current, however, if charge is removed from the CCD charge element then the p carriers will be pushed away (the reverse is true if the n− base is used to actuate), lowering the effective p-carrier base concentration on the left side of the thyristor in which case the thyristor will turn on if a voltage from anode to cathode is applied. We call this method of reducing the effective majority carrier concentration in the base, “priming.” After Vce is applied then the thyristor will conduct a holding charge even if the charge is then removed from the CCD element because the recombination current is supplied by the collector of the equivalent bipolar transistor. At the same time operation can be reversed as illustrated in FIGS. 21D and 21E where the priming of the thyristor occurs with the n-base rather than the p-base. In FIG. 21D a write charge coupled element is coupled by a dielectric to the n-base with a higher than normal base concentration to lower beta and prevent false triggers. In FIG. 21E there is another dielectric coupled from the p-base to a charge coupled element used as a barrier. On one side of this charge coupled element is a source of charge such as an input diode, on the other is an output charge coupled element. The charge coupled elements could be pinned or could be created by pulsing a gate over them. To prime the thyristor we can add charge to the “left of the n-base” charge coupled element which will push away majority electrons in the base and attract minority holes to effectively lower the beta of an npn channel along the left side of the thyristor structure. If the thyristor is primed then putting a voltage across the anode to cathode larger than a vbe+vce will cause it to turn on and it will stay on regardless of the state of the charge in the charge coupled element to the left of the n-base region (and oxide). Otherwise it will not turn on. This makes the left side of the structure in FIG. 21D the “write side.” On the other hand if the thyristor is on then the barrier will be lowered as the p+ base voltage will be high and will cause a barrier in the charge coupled element to its right (right of the oxide to its right) to fall. Even a small fall in the barrier height will allow charge to flow over the barrier and fill the output charge coupled element, as shown on the right bottom diagram of FIG. 21E, provided that the diode charge level is set just below or at the barrier full height. Nevertheless, if additional voltage is required to lower the barrier then voltage raising elements such as one or more series diode can be used to further raise the p+ voltage as illustrated in FIG. 21E to lower the barrier even more. On the other hand, if the thyristor is off then no current will be flowing and the p− region will fall to the voltage of the negative rail. This will raise the barrier in the charge coupled element to the right of the p-base as further illustrated in FIG. 21E on the bottom left. This ability to read the whether the thyristor is on or off makes the right side of the structure the “read side.” This combination of thyristor and CCD elements capable of both writing or reading a digital value will be called a Holdup Cell. These Holdup Cells can be used with a coupled CCD shift register which brings charge into the write side of Holdup Cells or can bring charge from the read side of the Holdup Cells as further illustrated in FIG. 21F. The structure to the right of the output charge coupled element is a reset to empty the output charge coupled element. This includes a barrier and a sink. The barrier can be commutated by the charge level in the charge coupled element next to the oxide using a voltage to barrier circuit or by coupling through an inverter to the cathode of the thyristor itself if diode level shift elements are used as in FIG. 21E. The diode elements coupled to the cathode of the thyristor also offer a voltage output to read the thyristor status, if used, as they will be high or low depending on whether the thyristor is on or off. Note that FIG. 21F only shows the two bases of the thyristor and is meant to be illustrative since the thyristor would likely be vertical and the diode, charge coupled element, and output charge coupled element horizontal with the shift register likely closer to the thyristor than shown. Consider the anode and cathode regions to be above and below the base regions with the base regions also flipped vertically such that the anode and cathode regions are not shown so as to not block the base regions in the illustration. Also note that the holding currents of thyristors in deep sub-micron processes can be as low as 1 pA with a Vce holding voltage of 0.3V to 0.6 from anode to cathode. A circuit can be used to set the anode to cathode voltage in conformance with the a minimum holding current, where said bias circuit reduces the Vce voltage and measures the current on a replica thyristor until just before turn off and then adjusts the Vce voltage to maintain that desired holding current level in a feedback loop. This adjusts for process and temperature variation. Where this structure is used as an SRAM it is important to note that the leakage of a deep submicron SRAM cell can be 42 pA typically due to all the junctions and contacts, thus the holding current of the thyristor when on can be less than the leakage of an SRAM cell in the same process.

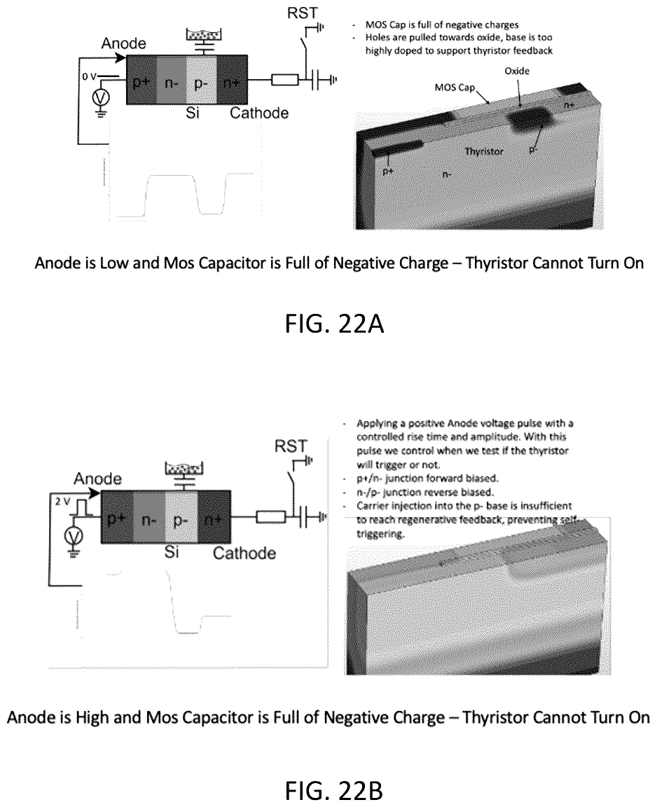

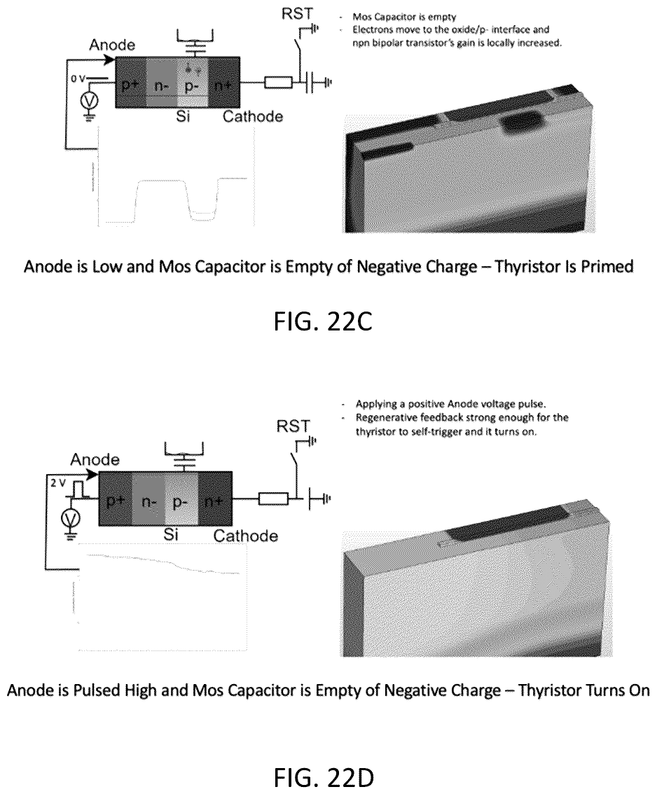

FIGS. 22A-22D show the operation of the superjunction in more detail. The capacitor in the diagram represents the isolator and the bucket the write side CCD storage input element. The thyristor is not actuated by a capacitively coupled current. Rather the effective concentration at the edge of the base is reduced and then providing a Vce above the holding requirement (bipolar vbe+vce) allows the thyristor to stay on. If the superjunction is not applied through the coupled CCD input element then the thyristor will not turn on when a Vce is applied. In FIG. 22A the anode is low and the MOS capacitor is full of negative charge, holes are pulled towards oxide, base is too highly doped to support thyristor feedback such that the thyristor cannot turn on. In FIG. 22B the anode is high and the MOS capacitor is full of negative charge such that the thyristor cannot turn on. The application of a positive anode voltage pulse with a controlled rise time and amplitude allows for control testing if the thyristor will trigger or not. With the p+/n− junction forward biased and the n−/p− junction reverse biased, carrier injection into the p− base is insufficient to reach regenerative feedback, preventing self-triggering. In FIG. 22C the anode is low and the MOS capacitor is empty of negative charge and the thyristor is primed. Electrons move to the oxide/p− interface and holes move away, the gain of the npn bipolar transistor is locally increased. In FIG. 22D the anode is pulsed high with a positive anode voltage pulse and the MOS capacitor is empty of negative charge and the thyristor turns on. Regenerative feedback is strong enough for the thyristor to self-trigger and the thyristor turns on. It will stay on regardless of the state of the charge coupled element since the collector can now provide the required minority carriers even with the slightly higher than usual majority base concentration, provided that the holding voltage is maintained and the current is not interrupted.

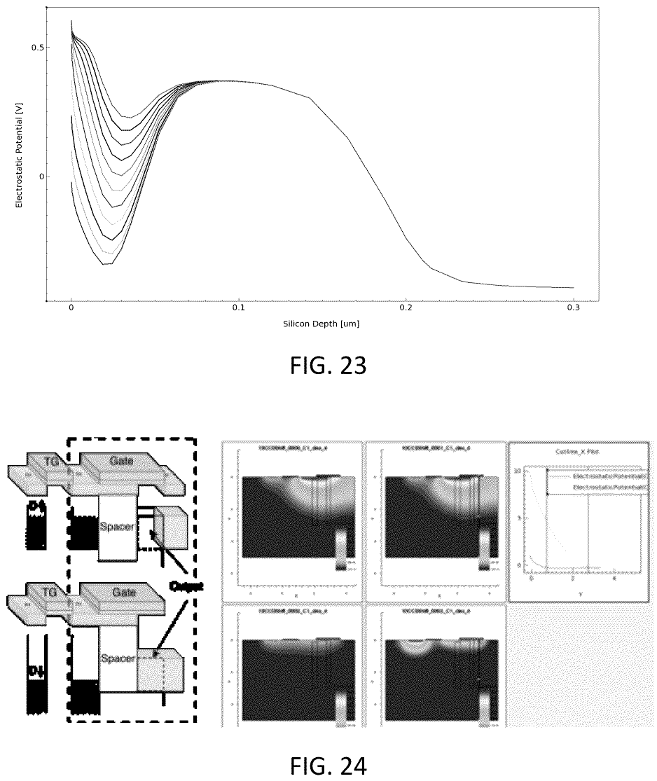

FIG. 23 is an electropotential plot of the thyristor base region as the charge in the charge coupled element coupled to the p− base region is varied. The x axis is depth from the base where it meets the isolation layer, to the left of which lies the dielectric and CCD input charge element. The y-axis is the electrical potential. The electropotential plot indicates how the superjunction effect varies the potential in the area close to the vertical isolator between the charge coupled element and the p− region priming thyristor strike or disabling thyristor operation. A similar construction could be coupled with the n− region in which case the absence of charge would disable and the provision of charge would prime. The raising of the anode then turns on the device which will hold until the voltage from anode to cathode drops below a minimum or the current is interrupted. The curves in the electropotential plot show different potentials in the base depending upon the charge level in the charge coupled element. At some charge level the thyristor is primed and would turn on if an anode to cathode voltage were applied.

### Static Logic

The hold current on the thyristor can be as low as 1 pA making the hold current lower than the leakage in even the smallest conventional logic gate. As this is a static hold (on or off), the thyristor/CCD combination can be used to enable static logic functionality. This functionality can be simply to remember the output of charge domain logic gates such that the output voltages remain available to other gates, or by using the actuating charge storage element of the superjunction enabled thyristor the base voltage may be used to raise or lower a barrier after resetting of the depletion (unless it is pinned in which case this is not necessary) so as to block or allow charge to flow to replenish the previous charge output of the gate. This could be actuated by a clock or change in a control input elsewhere in the logic circuit.

### Charge to Charge

The prior art AND gate shown in FIG. 4 suffered from the significant disadvantage that it could not allow the addition or removal of charge to commutate downstream digital gates nor did it teach the ability to accept charge as an input for digital gates. FIG. 24 shows the solution to this deficiency and is another case where use of the superjunction concept is made. Per FIG. 24 if charge fills the input charge element on the left side of the spacer, then the barrier on the right side of the spacer will rise. If a source of charge like a diode is placed next to the barrier, as shown in FIG. 24 to the right of the output charge coupled element, then when charge is removed the barrier will fall and charge will enter the output charge coupled element. If the charge is removed and the barrier rises then the charge will be pushed back into the diode. If the output barrier charge coupled element is used as the input charge coupled element of the next logic gate (which would be into the page), then it may be seen that a charge-to-charge gain element has been provided since it will be fully replenished to the level of the diode to the right regardless of the charge at the input. The charge could simultaneously produce a voltage gating signal for downstream logic gate if the floating poly were coupled to a gate input of another logic gate to allow for an overall charge-driven commutation with no need for clocking or the barriers created by superjunctions can be used to create logic functionality directly. For example, if a charge to barrier converter were arranged such that its output barrier was further into the page from the shown barrier, but this second barrier did not have a source of charge, and a similar output charge storage element were on the far side then an AND gate is provided. If both barriers were low then charge would flow into the output charge coupled element of the closest charge to barrier device and then into the output charge register over the second barrier at the output of the second charge to barrier device. On the other hand, if either of the barriers were high then charge would not frow to the output charge storage element of the AND gate. Note that a reset mechanism for the floating n+ and the gate need to be provided, however, this reset can be periodic since it is only needed when the voltages on the floating gates degenerate over multiple cycles. They can also be coupled to a single reset potential through a switching mechanism. At the same time, if a large enough charge can be assured to be put into or removed from the input then the reset may not be necessary.

On the right side of FIG. 24 a technology computer-aided design (TCAD) simulation, using Synopsis Sentaurus, of this circuit is shown. A diode on the far left is separated from the superjunction by a transfer gate. This transfer gate is not part of the superjunction charge to barrier or superjunction charge to charge device and just shows how charge might be moved into the input side of a superjunction based device. To be clear, a clock is not required by the superjunction to actuate. If charge is moved into its input then it will raise a barrier, if charge is removed, it will lower a barrier. This is an automatic commutation. The top left TCAD potential image is a reset phase where the floating diffusion and gate poly is reset to a reset voltage similar to how a floating diffusion in a 4T pixel is reset prior to movement of charge from a pinned photodiode (PPD). After the reset is released, there is almost the same similar potential situation as shown in the potential image to the right or middle top TCAD image. The farthest right line of this plot is the cutline used by Sentaurus TCAD to illustrate the potential plot in the plot on the far right of FIG. 24 and is labelled C1. The resulting potential related to the C1 cutline is shown in the farthest right plot in FIG. 24 and has an x-axis showing depth into silicon and a y-axis showing potential. Initially, the plot in the farthest right plot shows a deep depletion region. In the lower left TCAD potential image it is seen that the transfer gate is on and charge is transferred under the n+ causing the superjunction to reduce the voltage on the floating gate (the capacitor path including the diode capacitance, oxide capacitance, and reset capacitance). In the bottom right potential plot the transfer gate is turned again and it can be seen by the similarly located C1 cutline as in the plot above it that the barrier has risen as there is little to no depletion region left).

If a charge to charge converter is used such that only a small input charge is removed, and therefore the barrier falls only a small amount below its full height, the charge to charge converter can act as an inverting charge buffer by charging a charge coupled element on one side of the barrier provided that an input diode is placed on the other side of the barrier from the charge element. In this case the provided the diode's charge level is set at or just below the barrier full charge height such that even the small drop in the barrier height allows the diode to fully charge the charge storage element almost without regard to how little charge was moved into the input charge coupled element.

### Digital Charge Domain Logic

As was described in the prior art AND logic gate of FIG. 4, and as related to charge domain logic deficiencies of the prior art were described. The following charge domain logic gates fabricated in smaller than 180 nm processes or 40 nm or smaller FinFET processes do not suffer from these deficiencies. In Table 1 a number of devices in 5 nm technology are shown with the amount of energy used to produce the logic result compared to transistor based switches. In Table 2 a simple OR gate's improved switching speed when created using charge domain logic is shown as well. OR T means the speed with a transistor switch and OR CD means the speed with charge domain logic. From Table 1 and Table 2 as shown below, it can be seen that the power and performance improvement can be significant. Additional non-limiting examples of common logic gates that may be built from charge domain elements are disclosed below.

TABLE 1
Transistor vs. CD Power Savings
Performance Improvement - Power

| Cell | Energy | Units | Redux |
|---|---|---|---|
| OR Gate Transistor | 323 | aJ | — |
| OR Gate Charge Domain | 31.7 | aJ | 10.2x |
| Inverter Transistor | 72.57 | aJ | — |
| Inverter Charge Domain Based | 5.32 | aJ | 13.6x |
| SR Element Transistor | 310 | aJ | — |
| SR Element Charge Domain | 2.66 | aJ | 117x |
| 2-Half Adder Transistor | 646 | aJ | — |
| 2-Half Charge Domain | 32.3 | aJ | 20x |
| 3-Full Adder Transistor | 1615 | aJ | — |
| 3-Full Adder Charge Domain | 48.9 | aJ | 33x |
| Full Adder + 3 ANDs Transistor | 2584 | aJ | — |
| Full Adder + 3 ANDs CD | 144 | aJ | 17.9x |
| 4 × 4 Multiplier Transistor | 23665 | aJ | — |
| 4 × 4 Multiplier Charge Domain | 8787 | aJ | 2.6x |
| 6 × 6 Vedic Multiplier Transistor | 37293 | aJ | — |
| 6 × 6 Vedic Charge Domain | 1211 | aJ | 31x |
| Thyristor Read | 52 | aJ | — |

TABLE 2
OR Gate Transistor vs. CD Propagation Time
Performance Improvement - Speed

| Gate | Propagation Time | Unit | Improvement |
|---|---|---|---|
| OR T | 2400 | fs | — |
| OR CD | 868 | fs | 2.76x |

### AND Gate

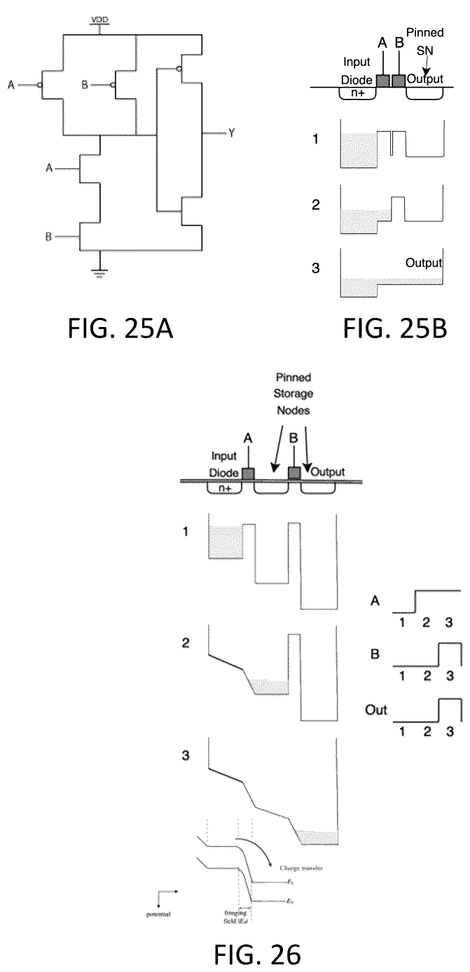

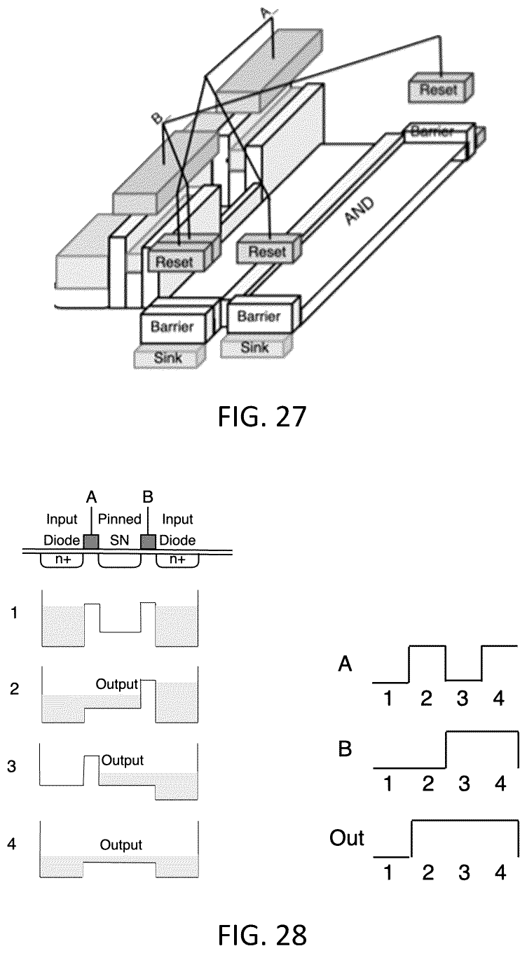

Three exemplary AND gates are shown in FIGS. 25A, 25B, 26, and 27. FIGS. 25A and 25B depict a simple barrier based AND gate. FIG. 25A is the schematic using transistor switches. If A and B are voltage high then the input to the output inverter is low and the output inverter is high. If either A or B are low then the input to the output inverter is high and the output is low. In the charge domain case as shown in FIG. 25B, there are barriers between the input diode and the output charge coupled element. If A and B are high then both barriers fall and charge transfers to the output charge coupled element. If either A or B are low voltage then charge cannot flow to the output charge coupled element and the output will be low. This implementation is compact but slow due to its lack of fringing field. FIG. 26 has artificially created pinned charge storage elements with the depletion region bottom being lower with each stage. These stages are separated by barriers as in FIG. 25B. The gate of FIG. 26 is faster but not practical due to the output charge potential being so low and difficult to couple to subsequent stages. FIG. 27 is a notch gate-based implementation. The notch gate-based implementation is interesting as it will accept either charge input or gate voltage input. In the first case, the input A and input B are actuated together by a clock. The notch gates charge when the voltage on input A and input B are raised to a higher voltage. After input A and input B fall to a lower voltage two notch gates worth of charge will transfer to the first long charge charge coupled element (which is not labelled AND). The height of the barrier between the first and second long charge coupled elements (the second labelled AND indicating AND output) is set so that only if both notch gates provide charge to the first gate, will charge flow into the output charge coupled element labelled AND. Thus, only if both inputs have received charge will the gate provide an output charge. The clock can be automatically actuated by a charge to voltage converter if charge is moved into either of the charge coupled input elements to the left of the A and B notch gates. Alternatively, input diodes can be used as a source of charge and A and B actuated by voltages. Only if the voltages on the gates of A and B are both raised after filling with charge will an AND output result. If either A or B are raised not enough charge will transfer to the middle charge coupled element to overflow the second barrier into the second charge coupled element labelled AND which is the output. If A and B are high then the barriers separating the charge coupled element not labelled AND will be discharged, while if either A or B are high then the barriers separating sinks on either side of the output charge coupled element labelled AND will fall and discharge said output charge coupled element. The Holdup Cells of the type illustrated in FIGS. 21D and 21E, and the Memory Page of FIG. 21F may be used to remember the output charge storage element digital value, and then used to recover the value in response to a refresh signal or commutation of a related gate within the digital logic equation. In other words, the changing of any node in the logic equation could trigger recovering of one or more stored logic outputs such that the charge domain logic system acts like a static logic system.

### OR Gate

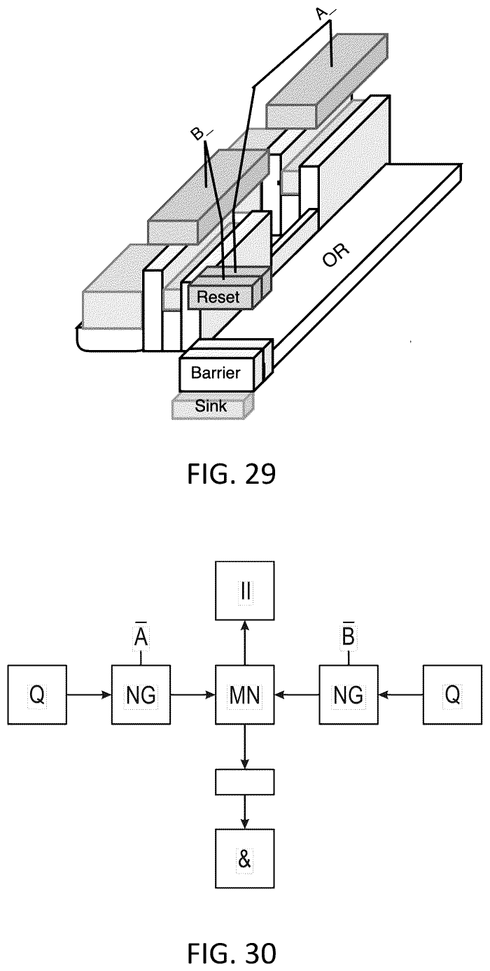

FIGS. 28 and 29 illustrate an exemplary OR gate. In FIG. 28 a simple OR gate is shown with two barriers and an output charge coupled element in the center. In FIG. 29 a notch gate implementation is shown. In FIG. 28 if the voltage on either gate input A or gate input B are initially low, then raising a voltage on either or both of them will lower a barrier and allow charge to enter the output charge coupled element. In FIG. 29, if either the gates A or B are initially high voltage such that charge enters their notch gate notches, and then either one or both of A and B are lowered then charge will transfer into the long output charge storage element labelled OR which is the output charge coupled element. If both the gates A and B are high voltage at the same time, the two barriers separating the OR output charge coupled element from a sink will go low and discharge the OR output charge coupled element.

### AND/OR

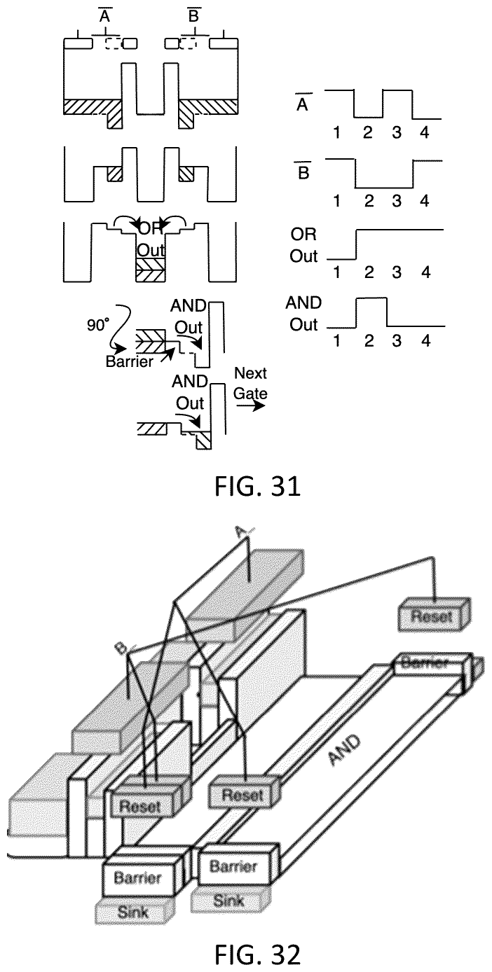

It is noted that an AND gate can be created by extending an OR gate with a barrier and an output charge storage node. FIG. 27 shows a block diagram of the functionality including two notch gates, an output charge coupled element to hold the OR output, a barrier and an AND output charge coupled element. FIGS. 27 and 32 illustrate this concept. Both an OR functionality and an AND functionality can be created from this construction. In FIG. 31 the additional barrier and output charge element are perpendicular to the lateral OR functionality.

### XOR Gate

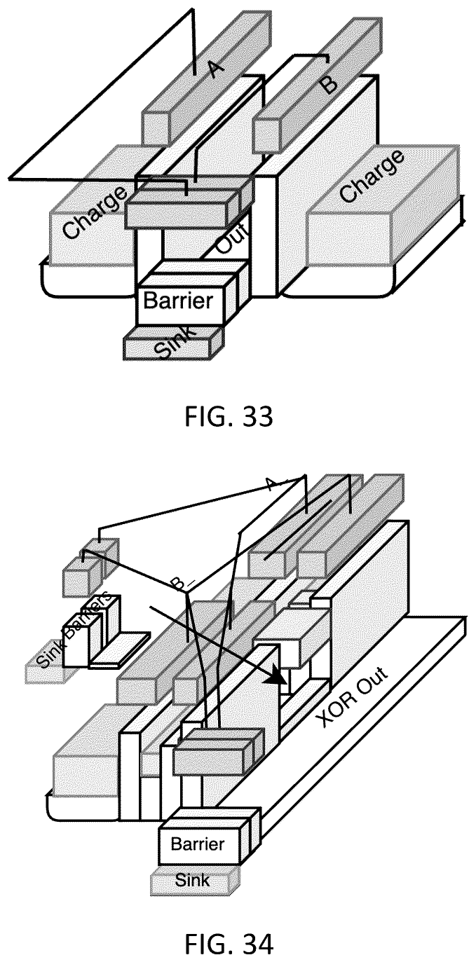

In FIG. 33 an exemplary exclusive or (XOR) gate is shown. If the voltage on input A is raised or the voltage on input B is raised, then charge held back by the barriers will enter the output charge coupled element in the center. When both input A and input B are raised to high voltage then the barriers separating the output charge storage element from the sink shown in FIG. 33 at the bottom of the diagram will fall. At the same time the barriers A and B separating the input charges will also fall so the sink will absorb the charge in the output charge coupled elements as well as these inputs charges. For this reason the input charges need to be finite and cannot be supplied in this configuration from a diode.

In FIG. 34 a notch based XOR gate which does not require an external reset is shown. If A and B gate voltage is high then the notch gates will be low and filled with charge awaiting further action and the two barriers separating the XOR Out charge coupled element will be low sinking any residual charge in said XOR Out charge coupled element. If either notch gate voltage falls with the other still high, then the additional barrier in series with the notch gate on the opposite input will fall and a notch of charge will be transferred to the XOR Out charge coupled element which would represent a digital ‘1’. For example if A is high voltage and B is low voltage then the fixed barrier in front of the B notch gate will fall quickly enough to ensure that the charge in the B notch gate can flow over it into the output before the charge in the B notch gate transfers to the charge coupled element between the two notch gates. If both gate input A and input B go high voltage then the two barriers separating the output charge coupled element labelled XOR Out from its sink on the bottom of the XOR Out charge coupled element will fall and the charge will be absorbed by the sink leaving a digital ‘0’. At the same time the two barriers in series with the notch gates will block the gates from spilling their charge and a small pair of fixed gates higher than the notch gate fixed barriers but lower than the series barriers that exists beyond the ends of the notch gates towards the center of the device will allow charge to flow into a charge coupled element between the two notch gates. A charge to voltage device will then lower a barrier causing the charge in the XOR Out charge coupled element to also flow into said charge coupled element between the two notch gates. Barriers designed to be higher than the gate separating the XOR Out from said charge coupled element between the two notch gates will then fall and allow the charge in the charge coupled element between the two notch gates to flow into a sink but only after the XOR Out charge coupled element has already flowed into the charge coupled element between the two notch gates. With this configuration both the 0/0 case and the 1/1 case will clear the output charge coupled element and the charge coupled element between the notch gates. This is an example of how to use the superjunction concept to create a level dependent gate with no external reset clock required. If holdup cells are further used to remember the output value of the gate, and/or the input values of the gate, then the state of the overall gate or its output can be made static.

### Inverter

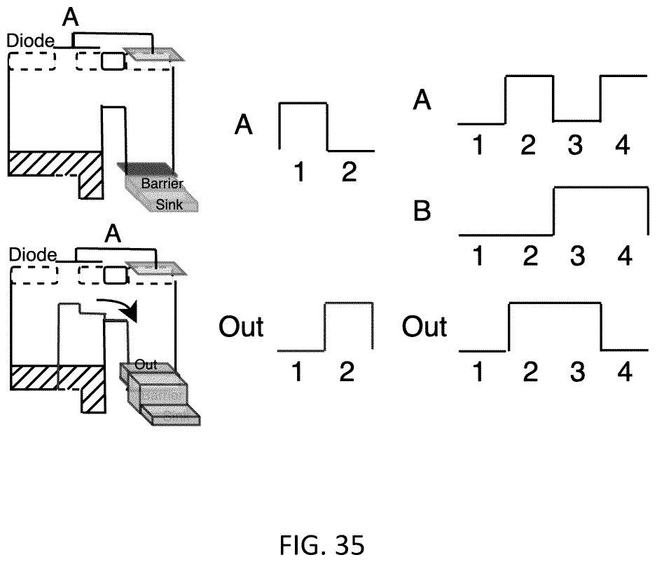

FIG. 35 shows an exemplary inverter. An input diode provides charge to the notch gate controlled by input gate A. Input gate A also controls a barrier between the output charge coupled element and a sink. If the voltage on input gate A goes high then the notch gate goes low and fills with charge. At the same time the barrier in series with the output charge coupled element which is also actuated by input A, which separates said output charge coupled element from the sink goes down and drains the output charge storage element. If the voltage on input A goes low then the charge in the notch spills into the output register. At the same time that the notch gate rises, the barrier between the output charge coupled element and the sink rises and blocks the sink leaving charge in the output charge coupled element. In this way a high voltage or ‘1’ on input A produces an output of no charge or ‘0’ and a low voltage or ‘0’ on input A produces an output of no charge or ‘1’ on the output charge coupled element.

### SR Latch

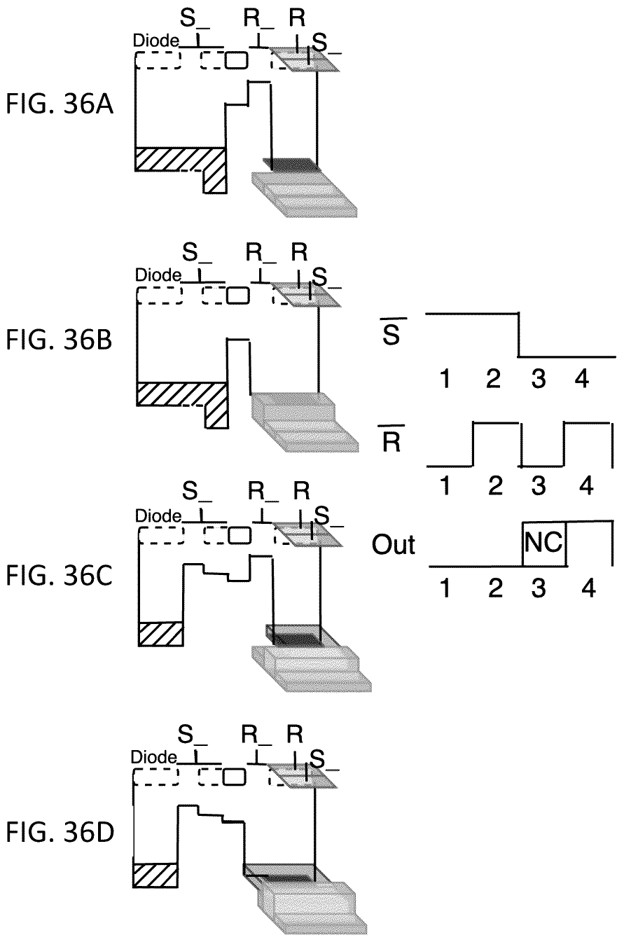

FIGS. 36A-36D illustrate the operation of a charge domain set-reset latch (SR-latch). In the example shown, the input diode is a source of charge and is coupled to a notch gate controlled by S_. S_ also controls a barrier in series with a sink. R_ is coupled to a barrier in series with the notch gate and R to a barrier in series with the sink and the S_ controlled barrier in series with the sink. If S_ is high and R_ is low then the output will have no charge indicating a ‘0’. If S_ and R_ are both high then the output will have no charge indicating a ‘0’. If S_ is low and R_ is low then the output will not change. If S_ is low and R_ is high then the output will have a charge indicating a ‘1’. If R_ and R are not both available then R_ can be coupled to an additional barrier with a source of charge on one side. The barrier can be placed next to the oxide of the p-base of the superjunction thyristor, with the anode connected to a positive supply. If R_ goes high, the barrier goes low and charge pours in above it, the superjunction oxide has charge in the charge coupled element so majority carriers are not pushed away and the minority carriers are not attracted so the thyristor is not primed and the R gate does not go high. If on the other hand R_ goes low voltage, then charge is pushed back into the diode, the carriers in the p-base are pushed away, minority carriers are attracted, the thyristor is primed and the R is pulled high voltage. In this way putting charge next to the thyristor n-base or p-base produces a buffer or a charge to voltage inverter.

### D-Latch

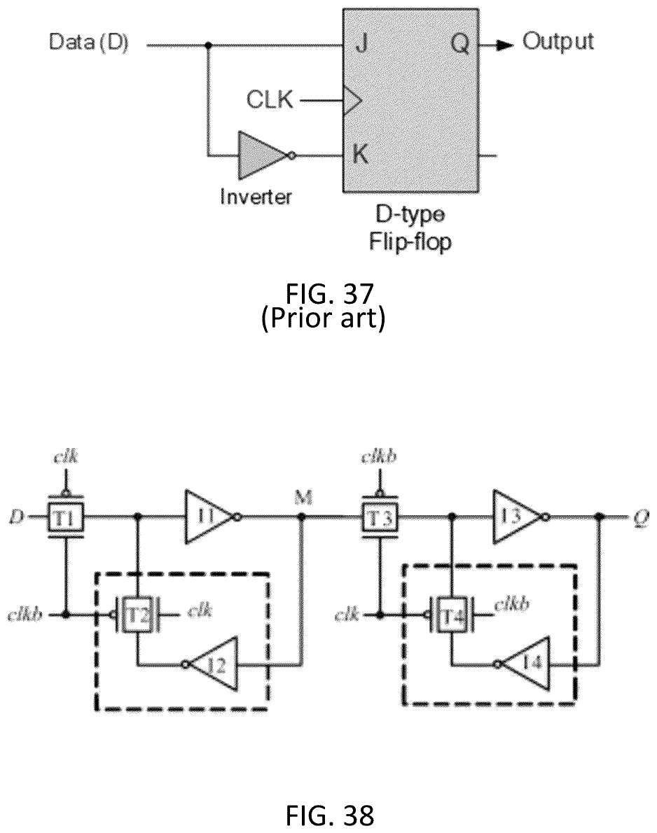

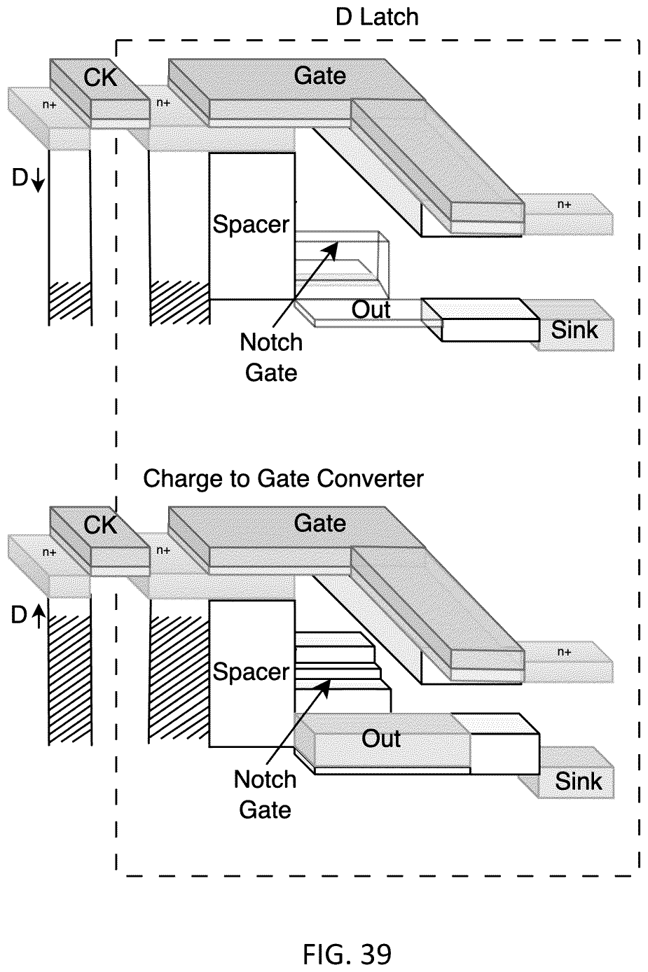

FIG. 37 is a block diagram of a data latch (D-latch). FIG. 38 is a circuit schematic of a D-latch built with transmission gate logic. FIG. 39 shows a charge domain implementation of a D-Latch. Charge is moved into the right side of the CK node when the clock is cycled. The transfer gate controlled by the CK node will either move a high charge or a low charge (actually takes charge away). If a high charge is moved then the gate voltage will drop, the barrier to the sink will rise, and the notch gate will rise. As the notch gate rises it will transfer charge to the output. Alternatively, if a low charge is moved (or removed) then the gate will rise, the barrier to the sink will fall and the output node will discharge. At the same time the notch gate will fall. The charge domain implementation is much smaller than a D-Latch created in the transistor domain. The charge domain implementation uses the superjunction concept to eliminate the need for a thyristor.

### T-Latch

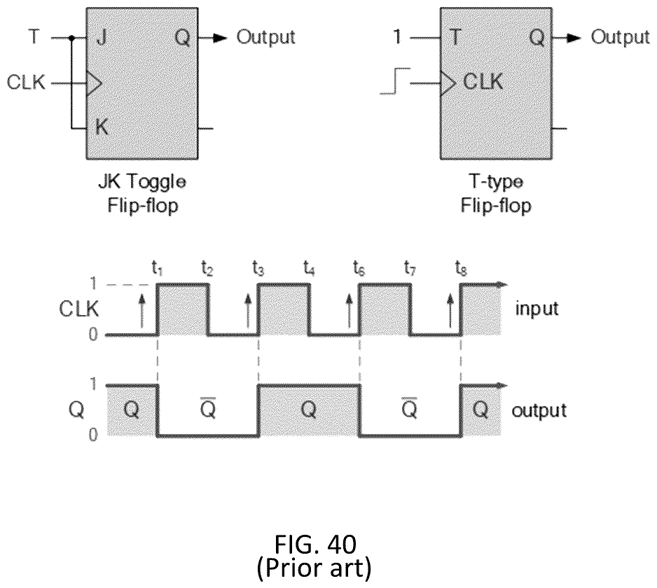

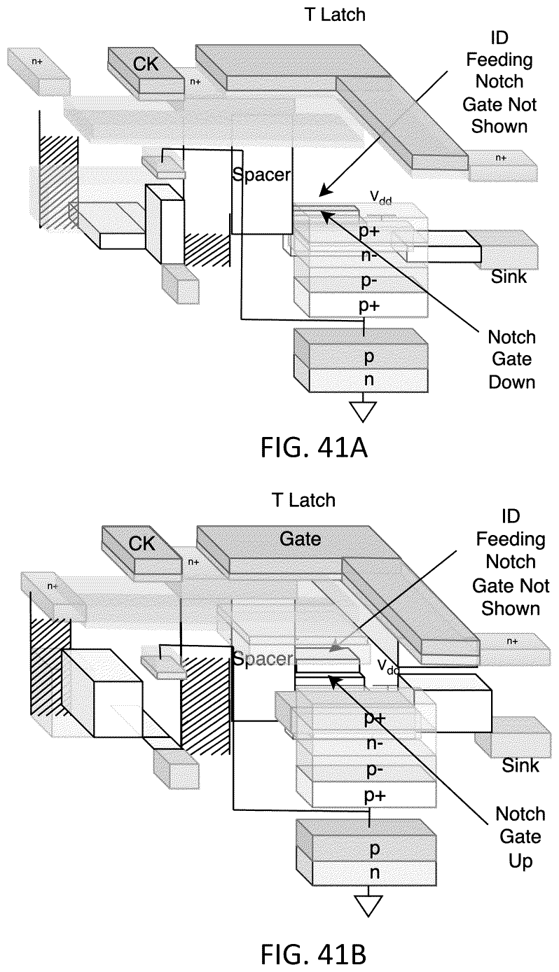

FIG. 40 is a block diagram of a toggle flip flop or T-latch. FIGS. 41A and 41B show the implementation of a toggle flip flop in the charge domain using the super junction concept. The input to the latch (to the right of the CK gate) is low charge in FIG. 41A. This is converted to a high voltage on the gate which will lower the notch gate feeding the output node into the page (perpendicular to the figure) and will lower a barrier to clear the output charge to a sink. The lowering of the output charge does not prime a superjunction thyristor which means the barrier in series with the sink next to CK will stay high. If CK is cycled then a large quantity of charge will propagate to the right side of the CK transfer gate. This will lower the voltage on the right side gate, raise the barrier to the sink and the notch gate, which will in turn supply charge to the output. The superjunction thyristor will be primed, which in turn will turn it on and lower the barrier next to the sink to the left of CK and discharge the input for the next CK cycle it again is ready to repeat the toggle process. The level shift diode is set to discharge the output gate capacitor to turn off the thyristor, however, it is sized such that it cannot alone provide a holding current. This allows the thyristor to turn off after the barrier gate has charged since it takes the combined capacitor and diode current to maintain the thyristor operation.

### Half Adder

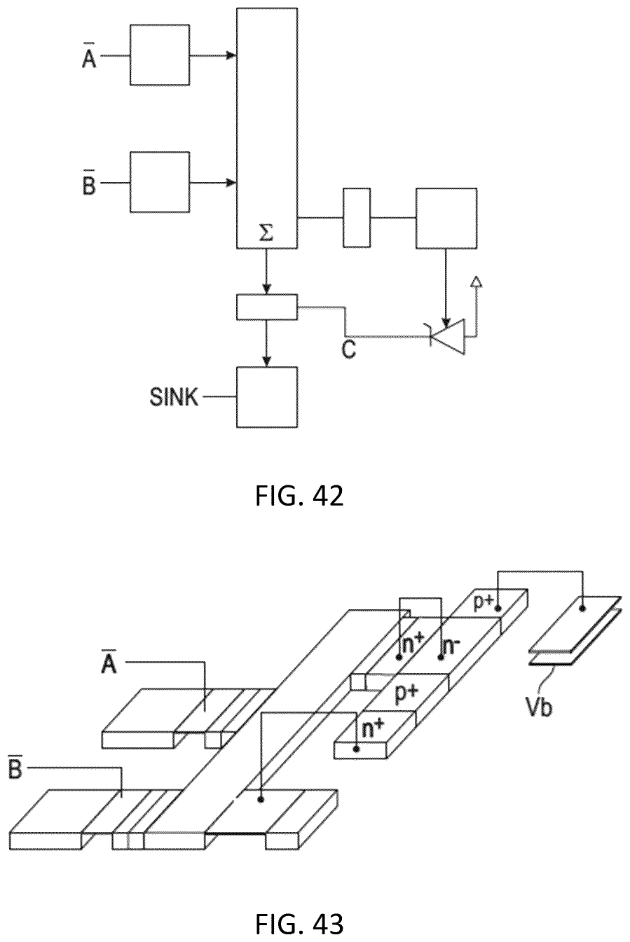

FIG. 42 shows a half adder charge domain block and FIG. 43 shows the layout. The idea here is that the barrier to the right of the output charge coupled element labelled with a Σ will allow a unit of charge to flow to the thyristor gate only if two units of charge are present in the Σ node. In this case the carry pushes charge into the thyristor which then turns on with its anode connected a dynamically preloaded capacitor (Vb). The charge in Vb is transferred to the barrier gate at the bottom of the diagram in FIG. 43 which lowers a barrier such that the charge in the long charge coupled element is drained into the sync on the bottom right corner of FIG. 43. The thyristor is coupled to a capacitor but could just as easily be coupled a supply node at its anode. Therefore, if only A_ or B_ go from high voltage to low voltage then the Σ node will be full of charge. If both go high then the carry will be high as a voltage output and the Σ node will be empty of charge.

### Full Adder

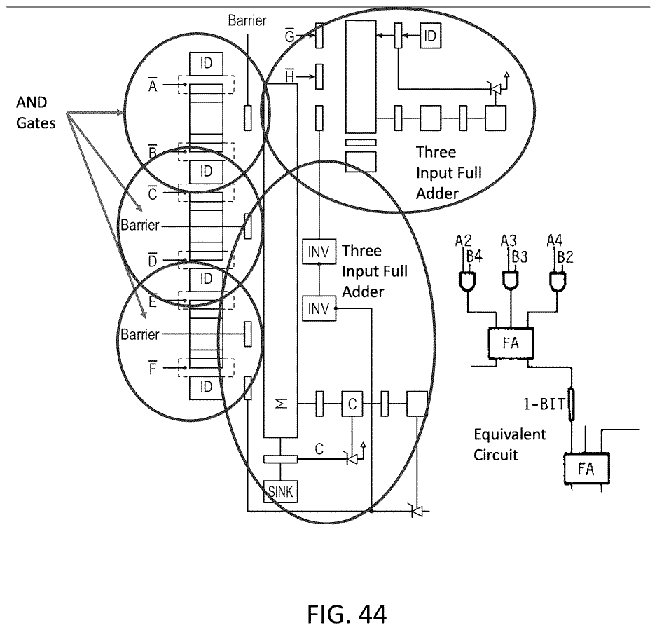

FIG. 44 shows a six input full adder. In this implementation three two input notch based AND gates provide charge to a common charge storage element labelled ‘Σ’ for sum. Barriers and charge to barrier devices (such as charge injection coupled thyristors) are used for the carry to strike a thyristor and to empty the Σ bucket per adder functionality shown in Table 3. Specifically, if there is a single unit of charge in Σ then sum is finished and carry stays zero. If there are two units of charge in Σ charge storage element then one unit flows over a barrier and is used to detect two packets of charge, and turn on a thyristor which in turn lowers a barrier to sink the charge in Σ. If there are three units of charge then the barrier to a fresh source of charge is enabled to fill the Σ charge storage element. Specifically, with three units of charge the Σ storage element is filled, spills over the first barrier and into the second barrier which triggers a thyristor through a delay to lower a barrier to empty the Σ charge storage element, but if there is spill over the second barrier then a thyristor will lower a barrier to a diode or other source of charge and maintain the fill on the Σ storage element. It is important that the timing of the emptying of the Σ node be set such that charge can reach the final carry charge coupled element and open the barrier to the charge source before the Σ is drained by the first thyristor lowering the barrier to the sink. Thyristor geometry can be used to control this timing or series inverters or buffers can be used to delay the discharge of Σ. The first sink needs to be limited in how much charge it can sink and also it needs to possible to clear the charge in it for a next event, otherwise it will not be possible to refill the Σ node. For example a well with a potential lower enough to capture the entire charge in Σ could be used rather than a diode, however, another barrier and diode at that lower potential to clear it during a reset phase could also be used. This way when the second thyristor lowers the barrier and refills the Σ the second sink will just be filled up by the filling diode which would not occur if the sink were a diode.

TABLE 3

| | |
|---|---|
| Inputs | Outputs |

| A | B | Cᵢₙ | Sum | Carry |
|---|---|---|---|---|
| 0 | 0 | 0 | 0 | 0 |
| 0 | 0 | 1 | 1 | 0 |
| 0 | 1 | 0 | 1 | 0 |
| 0 | 1 | 1 | 0 | 1 |
| 1 | 0 | 0 | 1 | 0 |
| 1 | 0 | 1 | 0 | 1 |
| 1 | 1 | 0 | 0 | 1 |
| 1 | 1 | 1 | 1 | 1 |

### Vedic Multiplier

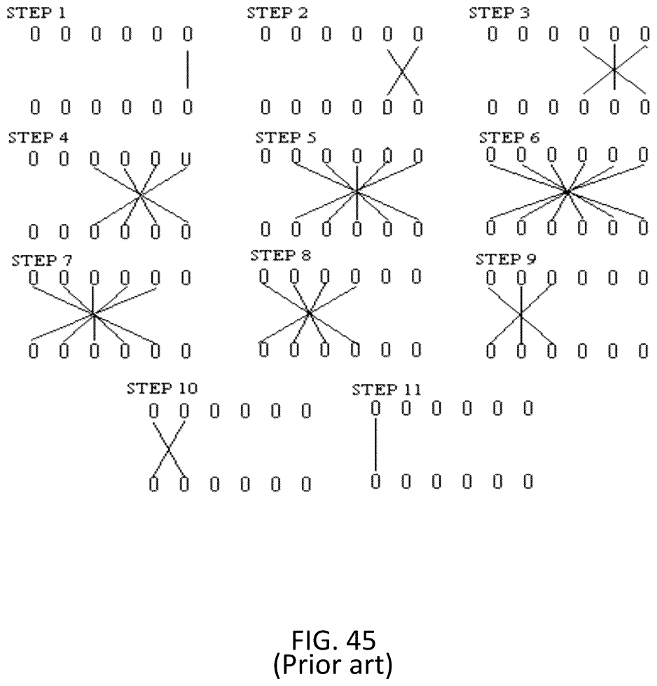

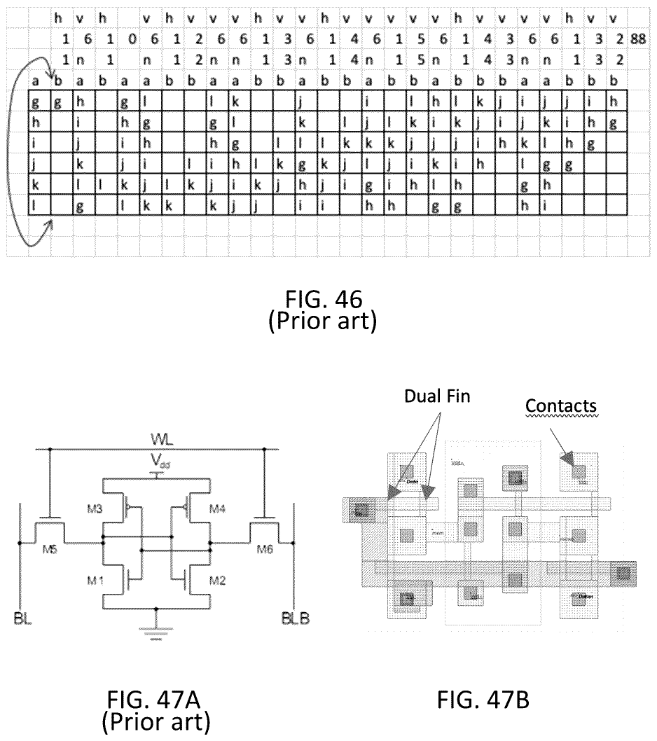

A vedic multiplier is an efficient multiplier that adds bits in specific symmetrical arrangements to reduce the number of cycles required for multiplication. FIG. 45 shows the steps required such that the lines represent the AND operations to multiply two six bit numbers. Note that six inputs is a non-limiting example and there is no limit to the number of bits a vedic multiplier configuration can multiply. Due to efficiency with shift registers as described earlier, the bits are efficiently moved to allow ANDing of bits according to the Vedic algorithm resulting in an extremely fast and compact design. This multiplier can be extended to multiplying numbers with an arbitrary number of bits using the same method. The snippet in FIG. 46 shows how the ANDs involving a, b and g, h, I, j, k, l can be performed with very little circuitry.

### Charge Domain Memory

FIG. 47A is the familiar SRAM structure with two back-to-back inverters and two access transistors. FIG. 47B is the layout in 5 nm lithography. It is interesting to note that it is the contacts, and not the Fins that set the size of the bitcell. As such SRAM does not shrink with lithography beyond about 12 nm since the contacts and active surrounding cannot be made any smaller. Charge domain implementation of the bitcell with a superjunction thyristor as in FIGS. 21D and 21E allows a significant shrink to about 1/10^{th} the size by taking out all of these contacts. The increased speed of the cell using the thyristor without so many capacitive junctions, and with less charge and commutation time including shootthrough, means that a CCD shift register can be clocked several times in the actuation time of a standard transistor based single bit cell. Therefore, a single contact, holdup cell and CCD shift registers may be substituted for multiple bit cells instead of 14 contacts in the most leading-edge SRAM bitcell. At present state of the art is 0.0199 sq. um for a bitcell. Charge domain implementation with a thyristor/charge domain storage element coupling (Holding Cell) can achieve about 0.002 sq. um. The transistor switch based SRAM bitcell leaks about 42 pA typically, while the holding current for the thyristor can be as small as 1 pA. This means that the thyristor, despite requiring a holding current, is still lower power than a static SRAM transistor switch based bitcell.

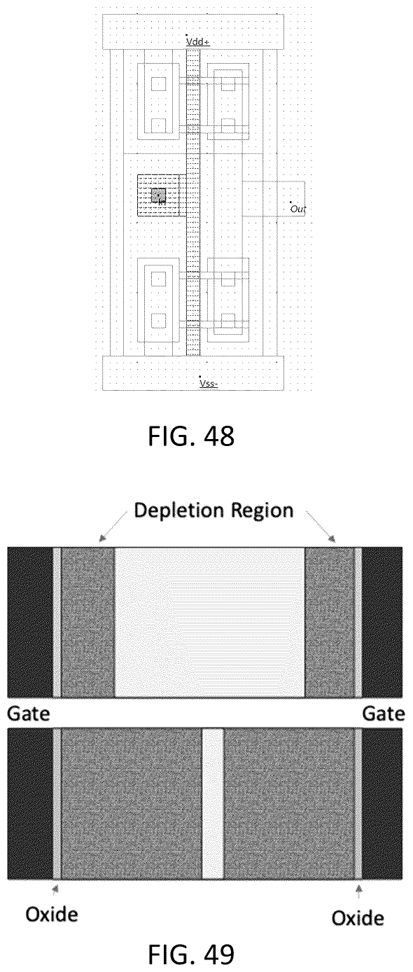

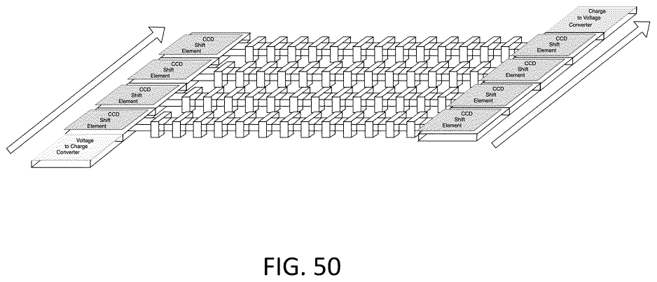

FIG. 48 shows a layout for a dual fin FinFET inverter. In the dual fin inverter significant wasted space can be observed between the two Fins of the transistor switches, between the FinFET devices itself, as well as caused by the distance to contacts for interconnects, separation of Fins and also due to n-well design rule spacing requirements. The purpose of the FinFETs is to drive large amounts of current in a small horizontal space (it is tall so equivalent width is big) so that it can do very quick transitions and produce high performance compute. This also means that shoot through is high and due to the proximity of gate and source, leakage is high. In charge domain digital structures use of this wasted space can be made by making a wider fin as there is more concern about depletion depth to ensure a reasonable number of electrons are held or to fabricate a thyristor, as well as by removing the area between the two Fins by using a single Fin, by removing the n-well and by removing most of the contacts and replacing them with a CCD shift register, which could be a two-dimensional CCD (2DCCD) shift register similar to that shown in FIG. 50. As shown in FIG. 49, a two-sided depletion region can be created to maximize electron storage. Furthermore, the poly at the top may be separated so as to create parallel depletion regions, which for example could create two parallel shift registers on a Fin. Alternatively, a shift register may be fabricated on one side of the fin and a thyristor fabricated on the other side to form the Holdup Cell type of configuration in FIGS. 21D and 21E, resulting in a parallel memory page structure as in FIG. 21F. This may not mean a lithography relaxation since a well-controlled Fin geometry and controlled gate width is still desired, however, in some cases it might allow fabrication of features in larger lithographies which match transistor switch performance of shift registers or digital gates of much smaller equivalent gate lithographies.

### DRAM

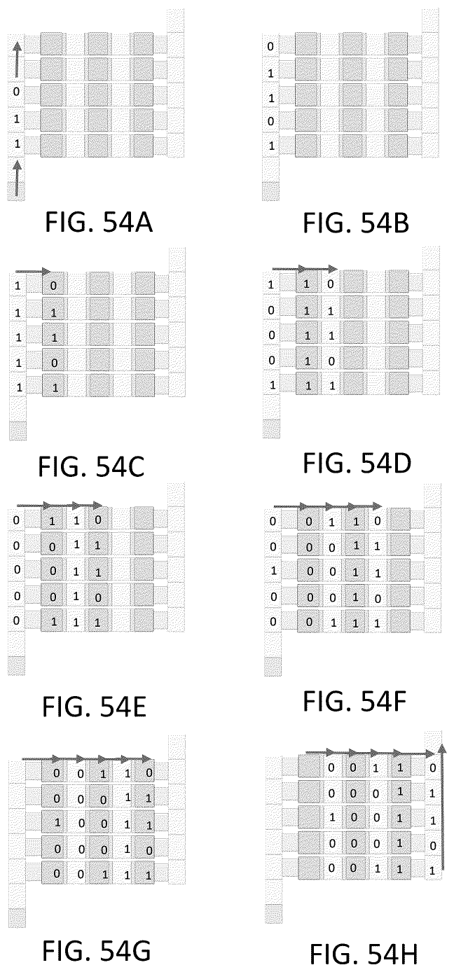

FIG. 50 shows a two-dimensional CCD shift register built using Fins in a 40 nm or smaller gate FinFET process. The shift register of FIG. 50 accepts charge information from a voltage to charge converter on the bottom left, which could simply be a diode with a contact to a voltage which raises and lowers a charge level above or below the bottom potential of the CCD shift register elements to provide charge or no charge each cycle or could be one of the many configurations taught in this disclosure. The horizontal elements are fabricated upon Fins and the vertical elements are fabricated on plateaus similar to the drain and source regions of a FinFET. In fact, a multi fin FinFET could be used as the page, such as a three fin FinFET, with vertical shift register elements fabricated on a plateau usually containing the drain or source. The poly gates surrounding the fins and are long continuous stripes common to each column tied back to clocking logic. For refresh the output can be returned to the input and the structure continuously cycled in conformance with the time constant needed to maintain the charge above a level if it's a ‘1’ as illustrated in FIG. 63. In FIG. 63, the charge in charge coupled element can be considered a ‘1’ above a threshold, and a ‘0’ below a threshold, and unknown between those thresholds as indicated by the highlighted center region. As the charge in a charge coupled element will decay it is important that the charge representing a ‘1’ is replenished before it reaches the highlighted area. The decay is illustrated by the line. In standard dynamic random-access memory (DRAM), amplifiers are used row by row to detect charge that has decayed and replenish it if the data was a high bit. In this case the charge to voltage converter then used to gate the input terminal such as a diode will perform this replenishment. The shift register first shifts information vertically, then horizontally, and finally vertically again to an output as further illustrated in FIG. 54.

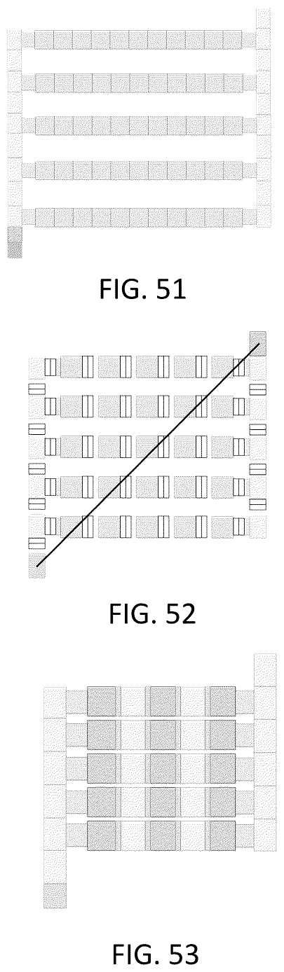

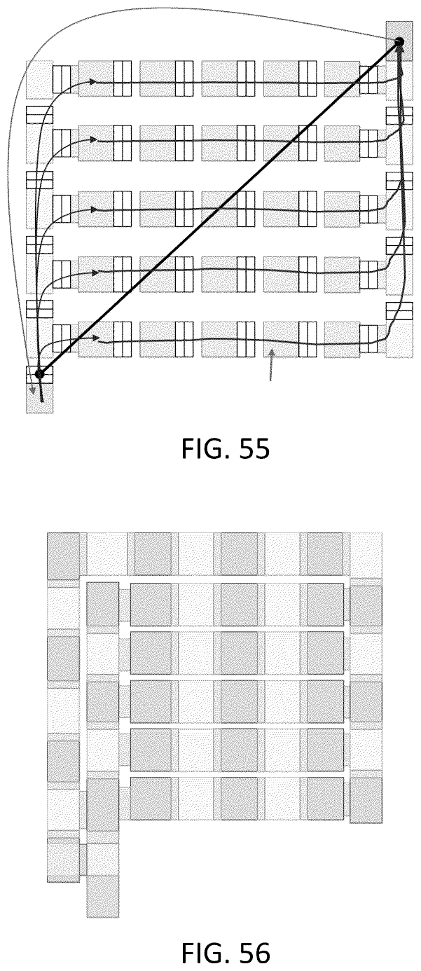

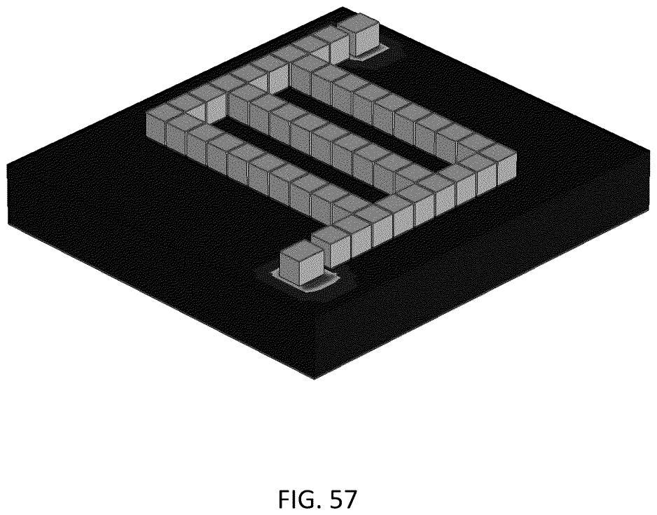

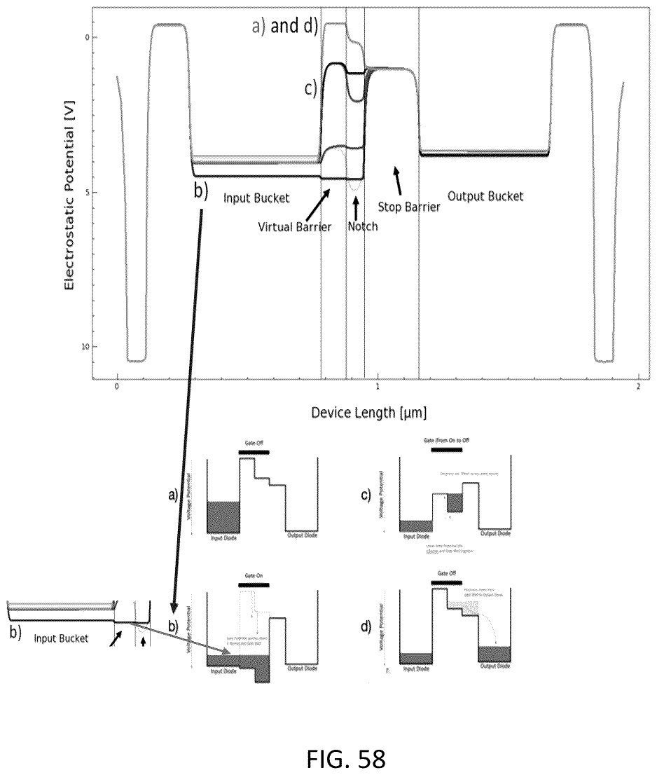

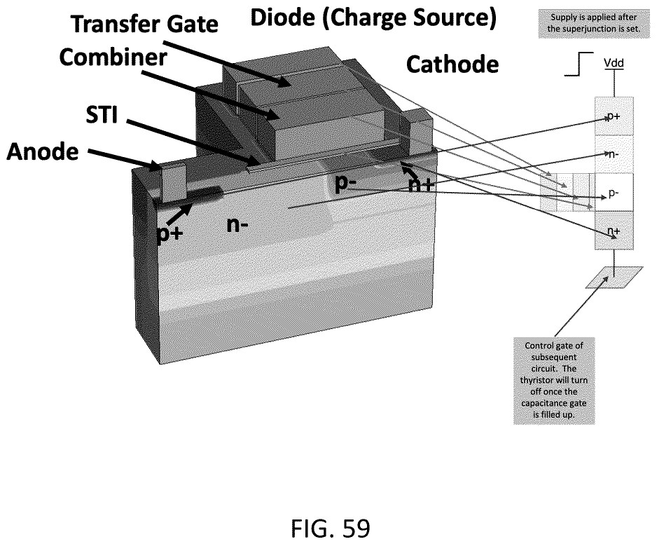

FIG. 51 shows a planar CCD shift register with a source of charge and a barrier to provide charge or not provide charge, representing a digital ‘1’ or ‘0’. Not providing charge would result in a zero once the previous charges were moved vertically from the first charge coupled element. A barrier on each side of the charge coupled element is required to provide isolation for this simple CCD shift register making this implementation large. FIG. 52 shows a notch gate based two-dimensional CCD shift register which uses the notch gates for the charge coupled element isolation and movement. The black line indicates cyclic recycling in that the output of the shift register at the top right can be returned using a charge to voltage converter raising or lowering the potential on an input diode or the notch gate to refresh the data cyclically on an ongoing basis in a mechanism analogous in its purpose to DRAM refresh. FIG. 53 shows the two-dimensional shift register implemented using the structure of FIG. 11 to reduce its size. FIG. 54 shows how data is shifted into, across and then out of the two-dimensional shift register with ‘1’ representing charge coupled elements with charge and ‘0’ representing charge coupled elements without charge. FIG. 55 shows how charge can be cycled continuously within the two-dimensional shift register to replenish the information. This includes vertical, then horizontal, then vertical and back to input cycling using a charge to voltage converter to commutate a notch gate and provide charge or not provide charge from an input diode depending upon the value at the output. This will also cause a full replenishment of the charge in the charge coupled elements and the same technique may be used for the other configurations of two-dimensional shift registers. FIG. 56 shows the shift register mechanism from FIG. 11 further extended to return charge from the output of the dimensional shift register and back to the input. The charge can be used to as the input to a charge to barrier buffer which will lower or raise a barrier commensurate with whether there is charge or no charge in the returned charge coupled element. The clocking of the shift register bringing the information from output to input can be done at a faster rate than, or the rest of the two-dimensional shift register can wait for, the output information to reach its input. FIG. 57 shows a TCAD Sentaurus view of a shift register similar to FIG. 51. FIG. 58 shows the TAD Sentaurus potentials of an actual notch gate being commutated. FIG. 59 shows a horizontal thyristor element further coupled to a charge coupled element for priming the thyristor. In this case a transfer gate will add charge to or not add charge to the charge coupled element next to a dielectric next to the p-base of the thyristor. If no charge is present then the thyristor is primed, if charge is present it is not. The diagram to the right of the Sentaurus TCAD three-dimensional drawing shows the thyristor and representations of the diode, transfer gate, charge coupled element and dielectric coupled to the p-base.

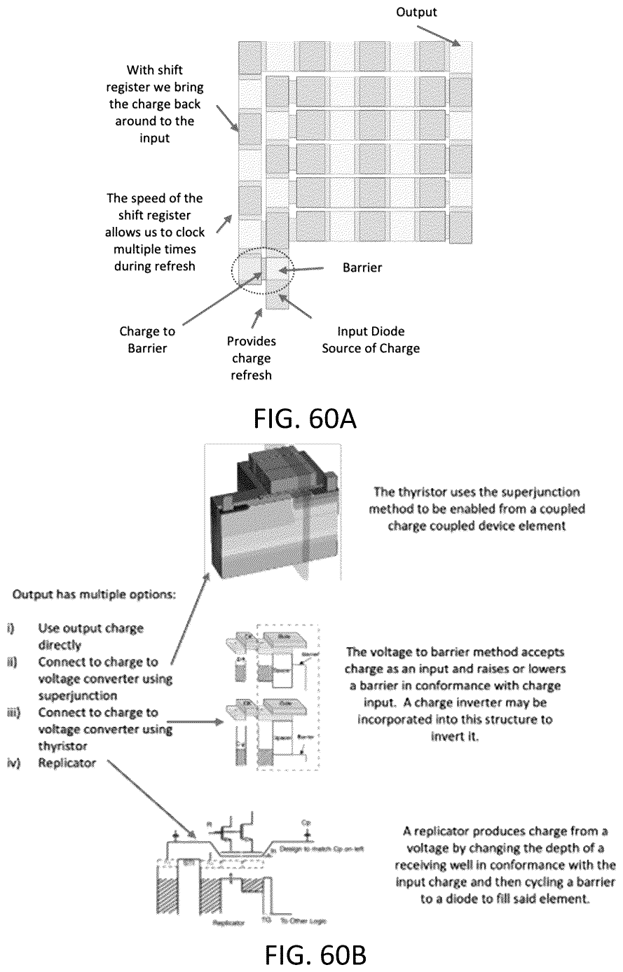

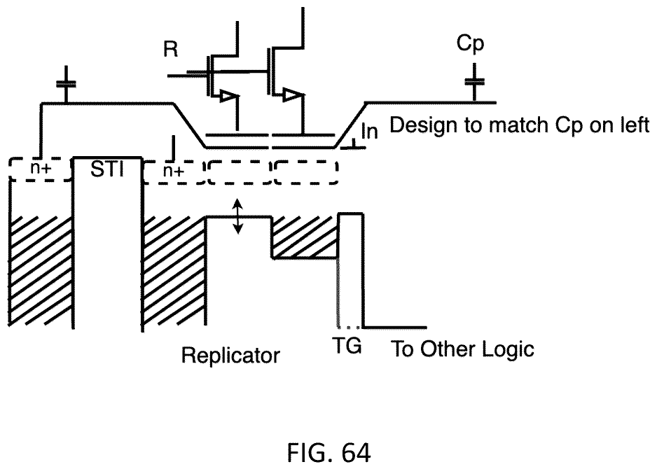

FIG. 60A shows a two-dimensional shift register to its input to cyclic refresh. FIG. 60B shows four different methods to return the output information from the output of the two-dimensional shift register to its input. The first method is to use a CCD shift register to bring the charge back to the input. Once in the same geographic region, the charge can be used to control a barrier or otherwise determine the charge that is loaded into the left vertical input of the two-dimensional shift register. The second method is to use a thyristor such that the output of the two-dimensional shift register is used to prime or not prime the thyristor. If the anode voltage is then raised the thyristor can be used to control a gate or other voltage controlled method to set the charge that is moved into the shift register in conformance with the data that is in the output charge coupled register. The third method is to use a charge to barrier device. This device could cycle through inverting pages of data and use only every second refresh (the one that didn't invert), or an inverter or other structure could be used at the input to ensure we do not invert the data, or an inverter could be switched in at the output when inverted data is present. The fourth method is to use a charge replicator as illustrated in FIG. 64 where moving charge under a floating n+ determines height of a wire connected barrier which blocks a charge coupled element which is then loaded with charge by raising and lowering the charge level on diode on the other side of a barrier from the output charge coupled element which charges it and then remove excess carriers above the barrier and output charge coupled element leaving an amount of charge proportional to the replicator input, which further would correspond to an above threshold charge level or a below threshold charge level. For example, if the barrier were at a level higher than the output charge coupled element then cycling the diode would leave charge in the output charge coupled element. On the other hand if the barrier level were brought to the level of the bottom of the output charge coupled output element or below it then when the diode were cycled charge would cross the lowered barrier, enter the output charge coupled element, and then be sunk back into the diode when the diode voltage was raised to push its charge level back below the level of the bottom of the output charge register bucket and barrier level. The gate marked In allows the output to enter the next gate, however, may be removed depending upon the configuration.

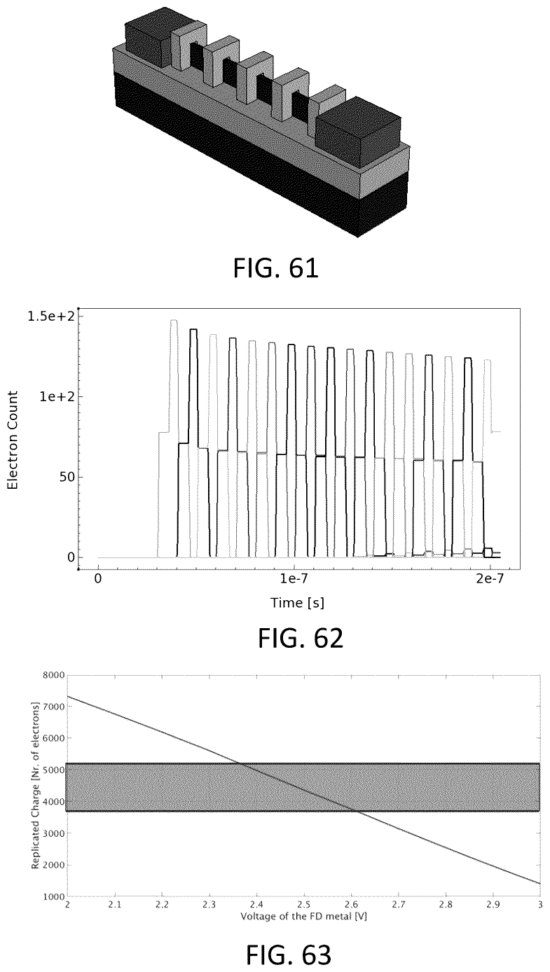

FIG. 61 shows a five element CCD shift register on a Fin. This register could hold two isolated pieces of charge information at a time. FIG. 62 shows the charge level as electrons are moved through the shift register of FIG. 9 in a TCAD Sentaurus simulation. Recall that FIG. 10 is a closeup of the charge in one element of the shift register in FIG. 9 during charge movement with the register having a half charge at first as it is sharing with an adjacent charge coupled element to its left, then rising to full charge as that adjacent charge coupled element barrier rises pushing its charge into the element and then falling to half as it shares a half charge with the element on its right and then the charge falls to zero as the barrier rises in the charge coupled element after the charge has flowed to the charge coupled element to its right.

### Electronic Design Automation

For use charge domain digital logic gates need to be incorporated into a standard digital flow. Design software tools typically divide design into front end and back end. To be useful, charge domain digital gates are incorporated seamlessly as new devices into front end design requiring only timing closure changes. The backend including register-transfer level (RTL) synthesis, parasitic extraction, and place and route will need to allow the combination of existing digital transistor based digital with charge domain elements. In the future, these tools may move exclusively to charge domain digital gates and abandon transistor based digital but this will take a long time. Adoption is accelerated if charge domain devices and transistor-based devices can be intermixed and designers can utilize a flow that they are used to.

The charge domain logic devices built with barriers, sinks, charge to barrier devices, charge to voltage devices, voltage to charge devices, thyristors, shift registers, holdup cells, etc., taught herein can be used to create all digital circuits both dynamic and static. Those skilled in the art will be able to combine these elements to synthesize all desired digital components including logic gates, memory, shift registers, as well as output drivers for these non-limiting aforementioned components.

While the preferred embodiments of the present invention have been disclosed herein, it will be appreciated that modification of these particular embodiments of the invention may be resorted to without departing from the scope of the invention as found in the appended claims.

Various modifications of the present invention, in addition to those shown and described herein, will be apparent to those skilled in the art of the above description. Such modifications are also intended to fall within the scope of the appended claims.

The foregoing description is illustrative of particular embodiments of the invention, but is not meant to be a limitation upon the practice thereof. The following claims, including all equivalents thereof, are intended to define the scope of the invention.

1. A shift register comprising:
a silicon fin structure;
a series of registers in the form of charge coupled elements positioned along the fin, the series of charge coupled elements defined by one or more of poly gates or metal gates; and
where said poly gates or said metal gates are clocked to move charge or the absence of charge along the fin.

2. The shift register of claim 1 further comprising pinning implants.

3. The shift register of claim 1 where gate geometry in 40 nm or smaller FinFET lithographies of the one or more of poly gates or metal gates use capacitive coupling between charge coupled elements as one of the mechanisms for charge transport as an additional transfer component to fringe effect, diffusion, and drift and to avoid a need for overlapping gates.

4. The shift register of claim 1 further comprising:
notch gates inserted between the series of registers to reduce an amount of charge transferred and to maximize fringe electric field and reduce the need for additional charge coupled elements to be used as isolation barriers.

5. A shift register device in 40 nm or smaller FinFET lithography or planar lithography smaller than 180 nm comprising:
a wide n-implant;
a thin p implant on one side of said n-implant;
poly or metal gates on either side of said n-implant, aligned with edges of said n-implant, where said poly or metal gates are further coupled to a clock;
a thin p implant under and aligned with an edge of said poly or metal gates furthest away from said n-implant on one side and adjacent to said n-implant but under a gate on an other side;
wherein the p-implant within the well creates a fixed barrier lower than the barrier created by the p implants outside the n-implant when on; and
wherein the p implants outside the n-implant create large fixed barriers such that when the clock is high voltage the area under the gate and between the p implant the n-implant and the area under the gate on the other side between the p-implant and the other side of the other gate comprise charge coupled elements; and
wherein when the gates low voltage or negative voltage the area under the n-implant comprises a charge coupled element.

6. A two-dimensional shift register device comprising:
an input charge coupled charge storage element;
an output charge coupled charge storage element;
a set of horizontal shift registers built upon parallel fins;
a first perpendicular shift register perpendicular to said set of horizontal shift registers, said first perpendicular shift register accepting input from said input charge coupled charge storage element, and having a first set of storage elements coupled to one side of said horizontal shift registers;
a second perpendicular shift register having one or more storage elements coupled to another side of said set of horizontal shift registers, where said second perpendicular shift register is further coupled to said output charge storage element; and
wherein information is shifted into said shift registers from said input element vertically, and then horizontally as a column through said set of horizontal shift registers, and then vertically into said output element.

7. The two-dimensional shift register device of claim 6 where said vertical shift registers are built on the silicon areas usually reserved for drain and source regions of a FinFET.

8. A charge actuation device producing a voltage output upon receipt or removal of an input charge, said charge actuation device comprising:
an input charge coupled element to accept input charge;
a dielectrically neutral spacer coupled to said input charge register;
a floating diffusion implanted above said input charge coupled element, said floating diffusion extending over a large portion or all of said dielectrically neutral spacer;
a dielectric, such as oxide, layer over the floating diffusion;
a floating polysilicon layer or metal layer over the portion of said oxide layer that is over the spacer;
a reset for periodic reset of said floating polysilicon layer and floating diffusion; and
wherein said polysilicon layer is capacitively charged or discharged by moving charge or removing charge from said input charge register and provided to subsequent voltage logic gates for control inputs.

9. A logic circuit fabricated using charge domain components comprising:
one or more voltage input terminals;
one or more output charge coupled elements;
an input diode, barriers and sink combinations to produce digital logic gate functionality; and
wherein the logic circuit is fabricated using a process lithography of less than or equal to 180 nm or a silicon fin lithography of equal to or less than 40 nm.

10. A digital logic circuit producing an inverter gate comprising:
a notch gate;
an output charge coupled element further coupled to the output side of said notch gate;
an input diode coupled to an input side of said notch gate;
a sink;
a barrier coupled between said output charge coupled element and said sink;
wherein a common input gate of said barrier and said gate input of said notch gate form a logic voltage control input, such that when a voltage on said logic voltage input is high then said barrier will fall, emptying said output charge coupled element into said sink over said barrier and lowering said notch gate to fill with charge from said diode; and
wherein when the voltage on said logic voltage input of said notch gate is low the barrier will rise blocking the output charge element from the sink and transferring charge to said output charge coupled element.

11. A charge to barrier control device comprising:
an input comprising a charge coupled element;
an electrically inert dielectric spacer isolated region;
an n+ implant extending from the top of a charge storage element across one of a majority of or all of the top of said electrically inert dielectric spacer;
a reset coupled to the n+ implant and poly layer to return their voltage to a reset level; and
an oxide and poly layer on top of said n+ implant and over said electrically inert dielectric spacer region further extending over silicon on the other side of said spacer from said input charge coupled element further raising or lowering a barrier underneath said extension in conformance with the charge moved into or out of the input charge coupled element.

12. A charge to charge device comprising:
said charge to barrier control device of claim 11;
a source of charge coupled to the output of said barrier control device;
wherein said source of charge fills the area over the barrier if said barrier is low and returns said charge to said source of charge if said barrier is high.

13. A charge to charge device comprising:
said charge to barrier control device of claim 11;
a source of charge coupled to a first side of said barrier control device;
an output charge coupled element coupled to a second side of said barrier control device from said source of charge;
a reset coupled to the poly and n+ regions to set its voltage to a reset voltage level or to the gate poly layer to return a floating voltage to a specific voltage level through capacitive coupling; and
wherein the lowering of said barrier below a level of said source of charge allows charge to flow over said barrier to said output charge coupled element where said output charge coupled element is replenished to the full level of the diode even if the charge moved into said input is only enough to marginally lower the output barrier of said barrier control device.

14. A charge to voltage converter comprising:
an input charge coupled device (CCD) storage element;
a thyristor n or p base region coupled to said CCD storage element through a dielectric; and
wherein a change in charge in said CCD storage element primes or disables said thyristor such that providing a voltage from anode to cathode will turn it on or keep it off, and
wherein the charge to voltage converter is fabricated on a semiconductor Fin.

15. A device to store a logic state comprising:
an input charge coupled element;
a thyristor with a doping level of majority carriers in the base set at a level that is electrically resistant to turn on if an anode to cathode voltage is applied, said base further coupled to said input charge storage element through a dielectric;
a control to establish a depletion region of said input charge storage element or a pinning control to permanently maintain said depletion region; and
wherein the region of said base closest to said dielectric is reduced in majority carrier concentration with the addition or removal of charge from or to said input charge storage element depending upon the polarity of said base; and
wherein a voltage from an anode to a cathode of said thyristor is applied to said thyristor in excess of that required for a holding current to be maintained, said thyristor actuating only if the base majority carrier concentration near the dielectric is lowered by said charge on said charge coupled element.

16. A device to recover a logic state from a thyristor acting as a digital memory comprising:
a source of charge;
a logic gate output charge coupled element;
a charge coupled element coupled to said source of charge and coupled through a dielectric to a base of a thyristor;
a control to recreate a depletion region of said input charge coupled element, and said logic gate output, or a pinning control to permanently maintain said depletion region;
wherein a voltage on the base of said thyristor raises or lowers a barrier in said charge coupled element in conformance with whether the thyristor is on and holding or off and thereby provides a path to replenish said logic gate output charge coupled element; and
wherein said logic gate output charge coupled element is coupled to said barrier, such that the logic gate output will be refreshed if its state was previously stored in said thyristor, such that if the base voltage is high and the barrier is below the level of the source of charge it will be refreshed or will remain low if the base voltage is low, implementing the equivalent of static logic.

17. The device of claim 16 further comprising:
a voltage level shift element, such as a diode, in series with said thyristor so as to increase or decrease the base voltage to enhance the rise or fall level of the barrier.

18. A memory device comprising:
a holdup device to store a logic state, said holdup device comprising:
an input charge coupled element;
a thyristor with a doping level of majority carriers in the base set at a level that is not easily conducive to turn on if an anode to cathode voltage is applied, said base further coupled to said input charge storage element through a dielectric;
a control to establish a depletion region of said input charge storage element or a pinning control to permanently maintain said depletion region; and
wherein the region of said base closest to said dielectric is reduced in majority carrier concentration with the addition or removal of charge from or to said input charge storage element depending upon the polarity of said base; and
wherein a voltage from an anode to a cathode of said thyristor is applied to said thyristor in excess of that required for a holding current to be maintained, said thyristor actuating only if the base majority carrier concentration near the dielectric is lowered by said charge on said charge coupled element; and
a device to recover a logic state from a thyristor acting as a digital memory, said device comprising:
a source of charge;
a charge coupled element coupled to said source of charge and further coupled through a dielectric to a base of a thyristor;
a control to recreate a depletion region of said input charge storage element or a pinning control to permanently maintain said depletion region; and
wherein a voltage on the base of said thyristor raises or lowers a barrier in said charge coupled element in conformance with whether the thyristor is on and holding or off and thereby provides a path to replenish said charge coupled element; and
wherein a logic gate output charge coupled element is coupled to said barrier and the other said of said barrier is coupled to a source of charge, such that the logic gate output will be refreshed if the base voltage is high and the barrier is below the level of the source of charge or will remain low if the base voltage is low; and
wherein said memory device further comprises:
one or more shift registers coupled to said charge coupled input element used for priming or not priming said thyristor and thereby storing information in said memory device and;
one or more shift registers coupled to an output charge coupled element instead of said logic gate output for reading information from said memory device; and
wherein said memory device allows input to be transferred to and stored or read and recovered from said memory device using the CCD shift register such that the number of contacts is reduced versus a digital switch based static memory bit cell.

19. A charge domain OR gate device comprising:
two or more sources of input charge;
two or more barriers coupled between said sources of input charge each actuated by a control gate;
an output charge coupled element coupled to said two or more barriers; and
wherein said barriers falling or rising in conformance with voltage on their control gates supply charge to said output charge storage element if any of the barriers fall.

20. A charge domain AND gate device comprising:
a source of input charge;
two or more barriers in series with said source of input charge each actuated by a control gate;
an output charge coupled element coupled to said two or more barriers in series; and
wherein said output charge coupled element receives charge from said source of input charge which will flow over said fallen barriers after all barriers have fallen in conformance with the voltages on their respective control gates.

21. A charge domain AND gate device comprising:
two or more sources of input charge;
a common charge coupled element;
two or more notch gates each coupled between said two or more sources of input charge and said common charge storage element each further actuated by a control gate;
an output charge coupled element coupled to said common charge coupled element by a fixed barrier whose height corresponds to or is below a level that would fill said common charge storage element less the charge associated with the charge that can be stored in one of said charge carrying notches of said notch gates; and
wherein said two or more notch gates fill said output charge coupled element only if all notch gates transfer charge to said common charge coupled element producing logic AND functionality.

22. An OR gate device comprising:
two or more separate input charge coupled elements;
two or more notch gates in series with each of said input charge coupled elements;
a common output charge storage element to each of said two or more notch gates such that charge from any notch gate will transfer to said common charge storage element;
a set of input control gates, one input control gate over each of said notch gates; and
wherein said input control gates causing charge to fill said two or more notch gates and to be transferred to said output charge coupled element in conformance with OR functionality.

23. An XOR gate device comprising:
two input charge coupled elements containing charge;
a set of first barriers with one barrier from said set of first barriers in series with each of said two input charge storage elements;
an output charge storage element between said first barriers;
two input control gates lowering or raising said barriers in conformance with logic voltage input signals;
two second barriers in series with said output charge storage element;
two additional control gates lowing or raising said second barriers in conformance with logic voltage inputs signals, each coupled to one of said input control gates;
a sink in series with said two second barriers; and
wherein if one or the other of said input control gates goes high, then charge will flow into said output charge storage element, however, if both are high then the charge will be sunk into said sink and the output will not contain charge.

24. An XOR gate device comprising:
a first input source of charge;
a second input source of charge;
a first notch gate coupled to said first input source of charge and a second notch gate coupled to said second input source charge, each notch gate also comprising a control gate to raise or lower each of said notch gates in conformance with a voltage;
a first large barrier coupled to the first notch gate and a second large barrier coupled to said second notch gate, where each of said large barriers is capable of completely blocking charge transfer from said notch gates if the barrier is high and allowing charge to flow from each of said notch gates if low, said large barriers also comprising a control gate to raise or lower each of said large barriers;
a single output charge coupled element coupled to both of said large barriers such that either or both of said notch gates can transfer charge to said output charge coupled element provided said large barriers are low;
a first drain fixed barrier coupled to said first notch gate, where the height of said fixed barrier is higher than the fixed barrier of said first notch gate, but smaller than the height of said first large barrier;
a second drain fixed barrier coupled to said second notch gate, where the height of said fixed barrier is higher than the fixed barrier of said second notch gate, but smaller than the height of said second large barrier;
a drain charge coupled element further coupled between said first and second drain fixed barriers;
a first reset barrier coupled between said output charge coupled element and a second reset barrier, said first reset barrier also comprising a control gate to raise or lower said barrier in conformance with a voltage;
a second reset barrier coupled between said first output barrier and a sink, said barrier also comprising a control gate to raise or lower said barrier in conformance with a voltage;
a third drain barrier coupled between said drain charge coupled element and a second sink; and
a fourth drain barrier coupled between said drain charge coupled element and said second sink; and
wherein said third drain barrier coupled element gate, first notch control gate, said second large barrier gate, and said first reset barrier gate are coupled and said fourth drain barrier gate, said second notch control gate, said first large barrier gate, and said second reset barrier gate are coupled;
wherein if the large barriers are high and the notch gates rise then charge will flow over the drain fixed barriers into said drain charge coupled element;
wherein if the first input notch control gate voltage goes high and second input notch control gate voltage goes low then the second large barrier will fall allowing the second notch gate to transfer charge to the output charge coupled element and if the second input notch control gate voltage goes high and first input notch control gate voltage goes low then the first large barrier will fall and the first notch gate will rise allowing first notch gate to transfer charge to the output charge coupled element;
wherein if both the first and the second notch gate control inputs go low voltage then the charge content of both notch gates will be transfer to said drain charge coupled element and the charge will be blocked from said second sink, however, if the charge from only one notch gate is transferred to said charge coupled element then the charge will be immediately drained into said second sink;
wherein the input of a charge to barrier device is further coupled to said drain charge coupled element and the barrier is coupled between said output charge coupled element and a third sink such that if there is charge in said drain charge coupled element then the charge to barrier device will allow transfer of the charge in said output charge coupled element to said third sink and leave said output charge coupled element empty of charge; and
wherein said configuration enabling XOR functionality includes integrated reset functionality.

25. A charge domain set-reset latch (SR-latch) device comprising:
a source of charge;
a notch gate;
a barrier taller than a fixed barrier of said notch gate capable of blocking charge transfer from said notch gate;
an output charge coupled element;
a first reset barrier and a second reset barrier between said output charge coupled element and a sink;
a first logic control input gate controlling said notch gate responsive to a set_bar;
a second logic control input gate controlling said taller barrier responsive to a reset_bar;
a third logic control input gate controlling said first reset barrier responsive to reset;
a fourth logic control input gate controlling said second reset barrier responsive to a set_bar;
wherein logic inputs on said set_bar, reset_bar, and said first reset and said second reset produce or remove charge in said output charge storage element according to SR latch functionality.

26. A charge domain D latch comprising:
an input source of charge whose charge levels correspond to a digital 0 or a digital 1;
an output charge storage element;
a transfer gate transferring said charge to the input charge storage element of a charge controlled barrier device, said charge controlled barrier device being a notch gate fed by a source of charge;
an extended gate coupled to the gate of said charge to barrier converter actuating a second barrier, said second barrier separating said output charge storage element from a sink;
wherein if charge is moved out of the input charge element of said charge controlled barrier device then said notch gate will fall and a notch will fill with charge from said source of charge and said second barrier will fall and direct charge said output charge storage element to the sink; and
wherein if charge added to said input charge element then the notch gate will rise and the second barrier will rise, causing the notch gate to spill charge into the output charge storage element and said second barrier to block the output charge storage element from the sink.

27. A charge domain T-Latch comprising:
an input source of charge coupled to the output of a charge to barrier device;
a charge coupled element coupled to said output and to a reset barrier, said reset barrier controlled by a control gate and further coupled to a sink;
an input transfer gate coupled to said charge coupled element and further to a charge to charge device;
the output of said charge to charge device further coupled to the input of said charge to barrier device and to a second reset barrier whose control gate is extended from the charge to charge control gate and which is further coupled to a second sink;
the n-base of a superjunction thyristor also coupled to the output of said charge to charge device, said superjunction thyristor further coupled to a level shift;
said level shift further coupled to the control gate of said reset barrier;
wherein if the input to said charge to charge device is initially without charge, then said output of said output barrier between said source of charge and said transfer gate will be low, and said reset barrier will be high causing charge to be available to said transfer gate;
wherein if CK is cycled, then charge will transfer to the input of said charge to charge device, which will add charge to the output of said charge to charge device, causing the barrier of said charge to barrier device to rise, and causing the thyristor to lower the barrier to the sync of the charge coupled element which will remove the charge in said charge coupled element and will disable the prime on the superjunction thyristor, and on the next CK charge will be removed from the input of said charge to charge device which will lower the second reset barrier to discharge the output of said charge to charge device and prepare the system for the next toggle, and also lower the notch gate.

28. A charge domain half adder device comprising:
a first source of input charge and a second source of input charge;
a first notch gate coupled to said first source of input charge and a second notch gate coupled to said second source of input charge;
a first control gate coupled to said first notch gate and a second control gate coupled to said second notch gate controlling the rise and fall of said notch gates;
a sum charge coupled element coupled to the output of both of said notch gates;
a fixed barrier whose height is higher than the charge from a single notch of charge but less that of two notches of charge coupled to said sum charge coupled element;
a carry charge coupled element coupled to said fixed barrier;
a charge to barrier device whose input is coupled to said carry charge coupled element, where said barrier falls if charge enters said carry; and
said barrier of said charge to barrier device is further coupled to a sink;
wherein if only one input transfer charge to said sum charge coupled element, then the charge represents an output ‘1’, however, if both charge coupled elements transfer charge then said carry will contain charge, representing a ‘1’ and the charge in said summing charge coupled element will be removed representing a ‘0’ thus producing half adder functionality.

29. A charge domain full adder device comprising:
three or more two input notch based AND gates coupled to a sum charge coupled element each through a barrier, said barrier coupled to said sum charge storage element taller than a single packet of notch charge but less than two notch charges;
a fixed barrier higher than a single notch of charge but less than two notches of charge coupled to said sum charge coupled element;
a carry charge coupled element coupled to said barrier, said carry charge coupled element coupled to a first charge to barrier lowering device such that if charge is present, said barrier lowering device will lower a barrier between said sum charge storage element and a sink which has the ability to remove the maximum charge or somewhat more than the maximum charge in the sum node but is not able to sink additional charge;
a second barrier coupled to said sum charge coupled element taller than a single packet of notch charge but less than two notch charges, said second charge storage barrier coupled to a second charge to barrier lowering device such that if charge is present, said second charge to barrier lowering device lowers a barrier between said sum charge element and a source of charge such that said sum charge storage element is filled to or just below said first charge barrier level, where said first charge to barrier device is delayed such that said second charge to barrier device will actuate before said second charge to barrier device ensuring that the charge will not be removed in said sum charge storage element in the case of a carry.

30. A charge domain multiplier device comprising:
two input shift registers containing a two binary numbers of any number of bits;
a control responsive to the vedic algorithm;
a set of AND gates coupled to said shift registers; and
wherein the numbers in said two input shift registers are shifted and ANDed according to the vedic algorithm to multiply the two binary numbers.

31. A charge domain memory page comprising:
a Fin;
two or more holdup cell devices;
a CCD shift register; and
wherein said memory page devices are distributed along said Fin so that information may be stored and recovered using said CCD shift register, avoiding the need for large numbers of contacts across multiple bitcells and to form a memory array.

32. The charge domain memory page of claim 31 further comprising:
a voltage to charge device input on one side of said array; and
a charge to voltage device output on another side of said array;
wherein shift register digital voltage values are coupled from said array or into said array from or to external voltages so as to be compatible with voltage-based readers.

33. A dual CCD shift register memory page device comprising:
a Fin; and
one or more MOS capacitors with poly separated at the top of the Fin to form two vertical depletion MOS capacitors.

34. A holdup cell shift register device comprising:
a Fin;
a CCD shift register fabricated on one side of said Fin;
a vertical thyristor fabricated on another side of said Fin; and
a vertical dielectric to separate CCD register elements from a base region of said thyristor.

35. A DRAM page comprising:
one or more rows of CCD shift registers each of the CCD shift registers having gates, the gates of said shift registers being common stripes connected to control gates which are further coupled to a control;
two columns of CCD shift registers having gates;
an input terminal;
an output terminal; and
wherein each of said one or more rows of CCD shift registers is coupled to a first common column shift register on one side for accepting and shifting input charge;
wherein gates of said column shift register are coupled to a column gate control;
wherein each of said rows are coupled to a second common column shift register on the side opposite side from said first common column shift register;
wherein said first shift register is coupled to said input terminal;
wherein said second shift register is coupled to said output terminal; and
wherein digital information is clocked into said shift register as a high charge or low charge from said input terminal, first vertically on the first column shift register, then horizontally across the parallel row shift registers, and finally vertically again with said second shift register to said output terminal in conformance with gate control on said control gates; and
wherein said DRAM is further fabricated on less than 180 nm lithography or 40 nm FinFET equivalent gate lithography process.

36. The DRAM page of claim 35 further comprising a refresh device where said output terminal is coupled to said input terminal and said control gates rotate charge stored on the DRAM page to refresh the DRAM page according to a holdup time.

37. The DRAM page of claim 36 wherein the refresh device further comprises a charge to charge buffer to replenish the charge state of information as it is passed from the output terminal to the input terminal.

38. The DRAM page of claim 35 wherein the horizontal CCD shift registers are fabricated upon a Fin.

39. The DRAM page of claim 35 wherein refresh gain occurs due to the return of output information to the input such that the charge to voltage and input terminal perform the charge gain in place of amplifiers in transistor based DRAM or where said replenishment is done by a charge-to-charge buffer.

40. The DRAM page of claim 35 where said input terminal is a diode whose charge level can be modulated according to a bitstream on a control wire so as to fill the adjacent CCD shift register charge coupled element or drop the charge level below the level of said charge storage element to empty charge from said CCD shift register input charge coupled element.

41. A dynamic charge domain logic gate converted to a static gate by coupling an output of said dynamic charge domain logic gate to a memory page device or holdup cell, where said memory page device refreshes said logic gate in conformance with a control command or a control command is generated in conformance with an input change within the logic algorithm of which the logic gate is a part.

42. A reset device coupled to charge coupled elements of a charge domain gate, further coupled to a reset signal, where said reset signal removes the charge from said charge coupled elements by sinking charge through one or more barriers to one or more sinks.

43. The reset device of claim 42 further comprising an actuation device such that said charge actuation device produces said reset signal in conformance with movement of charge.

44. A charge actuated driver device comprising;
a thyristor base coupled to a charge coupled element through a dielectric; and
wherein priming of said thyristor is by adding or removing charge to or from said charge coupled element, said thyristor further coupled to a voltage source and to a load, which are one or more of capacitances of on chip metal lines, capacitors, resistors, or other loads, or an off-chip load.

45. Charge domain digital logic gates incorporated into a standard digital flow such that front end design only requires changes to timing and the backend takes care of register-transfer level (RTL) and polygon placement using charge domain devices intermixed with transistor switch based devices or only charge domain digital logic gates.

46. A charge replicator device comprising:
an input diode into which charge might be moved;
a separate diode coupled to a barrier, where the gate control input of said barrier is coupled by a wire to said input diode, causing the barrier height to be proportional to the charge input into said input diode, said separate diode further having a wire connection to raise or lower the charge level under said separate diode;
a charge coupled element coupled to the other side of said barrier; and
wherein a voltage is lowered and then raised to cycle charge higher than the highest expected barrier height and then below the lowest expected level of said barrier such that said charge coupled element is filled with charge to the level of the barrier, said charge constituting a replicated charge.

47. A holding current calibration device comprising:
a replica thyristor structure;
a feedback means;
where the feedback means adjusts the voltage across said thyristor structure until just before the thyristor turns off,
and wherein the voltage from anode to cathode of said replica thyristor established by said feedback is used to set the anode to cathode voltage of other thyristors used in an integrated circuit.
